(19) United States
(12) Patent Application Publication
(10) Pub. No.: US 2024/0128721 A1
(43) Pub. Date: Apr. 18, 2024

(54) SURFACE EMITTING LASER

(71) Applicant: SONY GROUP CORPORATION, TOKYO (JP)

(72) Inventors: SHUHEI YAMAGUCHI, TOKYO (JP); HIDEKI WATANABE, TOKYO (JP); RINTARO KODA, TOKYO (JP)

(21) Appl. No.: 18/264,545

(22) PCT Filed: Jan. 19, 2022
(86) PCT No.: PCT/JP2022/001682

§ 371 Date: Aug. 7, 2023

(30) Foreign Application Priority Data
Feb. 19, 2021 (JP) 2021-025175

(51) Int. Cl. H01S 5/183

(52) U.S. Cl. CPC H01S 5/1833; H01S 5/18325; H01S 5/18347; H01S 5/18361

(57) ABSTRACT

The present technology provides a surface emitting laser that can be manufactured with an excellent yield and has a configuration of confining a current and light. The present technology provides a surface emitting laser including a first structure including a first multilayer film reflector, a second structure including a second multilayer film reflector, and a resonator disposed between the first and second structures and including an active layer, in which a joint portion exists in at least one of inside the first structure, inside the second structure, inside the resonator, between the resonator and the first structure, or between the resonator and the second structure, and a first confinement portion that confines a current is provided in at least one of first or second constituent portion joined at the joint portion, and a second confinement portion that confines at least light of a current or light is provided in at least one of the first or second constituent portion.

### TECHNICAL FIELD

The technology according to the present disclosure (hereinafter also referred to as “the present technology”) relates to a surface emitting laser.

### BACKGROUND ART

Conventionally, for example, in an AlGaAs-based compound semiconductor, a surface emitting laser in which an active layer and a current confinement layer of an oxidation confinement type (configuration of confining a current and light) are arranged between first and second multilayer film reflectors is known (see, for example, Patent Document 1).

### CITATION LIST

Patent Document
Patent Document 1: Japanese Patent Application Laid-Open No. 2006-351798

### SUMMARY OF THE INVENTION

### Problems to be Solved by the Invention

However, in the conventional surface emitting laser, there is room for improvement in providing a surface emitting laser that can be manufactured with an excellent yield and has a configuration of confining a current and light.

Therefore, a main object of the present technology is to provide a surface emitting laser that can be manufactured with an excellent yield and has a configuration of confining a current and light.

### Solutions to Problems

The present technology provides a surface emitting laser, including:

a first structure including a first multilayer film reflector;

a second structure including a second multilayer film reflector; and

a resonator disposed between the first and second structures and including an active layer, in which

a joint portion exists in at least one of inside the first structure, inside the second structure, inside the resonator, between the resonator and the first structure, or between the resonator and the second structure, and

a first confinement portion that confines a current is provided in at least one of a first constituent portion on one side or a second constituent portion on another side of the joint portion, and a second confinement portion that confines at least light of a current or light is provided in at least one of the first or second constituent portion.

The first and second confinement portions may be provided in one of the first and second constituent portions.

The first confinement portion may be provided in one of the first and second constituent portions, and the second confinement portion may be provided in the other.

The second confinement portion may be provided on a first joint surface that is a joint surface of the first constituent portion with the second constituent portion and/or a second joint surface that is a joint surface of the second constituent portion with the first constituent portion.

The first confinement portion may be provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

The first confinement portion may be provided in a region including a first joint surface that is a joint surface of the first constituent portion with the second constituent portion and/or a region including a second joint surface that is a joint surface of the second constituent portion with the first constituent portion.

The second confinement portion may be provided on a first joint surface that is a joint surface of the first constituent portion with the second constituent portion and/or a second joint surface that is a joint surface of the second constituent portion with the first constituent portion, and the first confinement portion may be provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

The second confinement portion may be provided on a first joint surface that is a joint surface of the first constituent portion with the second constituent portion and/or a second joint surface that is a joint surface of the second constituent portion with the first constituent portion, and the first confinement portion may be provided in a region of the first constituent portion including a first joint surface that is a joint surface of the first constituent portion with the second constituent portion and/or a region of the second constituent portion including a second joint surface that is a joint surface of the second constituent portion with the first constituent portion.

The resonator may further include first and second cladding layers disposed at positions sandwiching the active layer, and the joint portion may exist inside at least one of the first or second cladding layer.

The second confinement portion may be a layer provided on at least one of the first or second joint surface and existing in a circular recessed portion.

The layer may be a low refractive index layer having a lower refractive index lower than a refractive index of a portion of the first constituent portion and/or the second constituent portion inside the recess.

The low refractive index layer may have a semi-insulating property or an insulating property.

The layer may have a semi-insulating property or an insulating property.

The cross section of the recess may have a shape that becomes shallower as approaching the at least part of the central portion.

The first confinement portion may have a higher electrical resistance than a portion surrounded by the first confinement portion.

The first confinement portion may be a layer into which ions are implanted.

The first confinement portion and a portion surrounded by the first confinement portion may be formed by a compound semiconductor, and the first confinement portion may have a larger band gap than a portion surrounded by the first confinement portion.

The first confinement portion may be a layer into which impurities are diffused.

The first confinement portion may be a layer into which ions are implanted and impurities are diffused.

The first confinement portion may be a layer into which ions are implanted and/or impurities are diffused.

### BRIEF DESCRIPTION OF DRAWINGS

FIG. 1 is a cross-sectional view illustrating a configuration of a surface emitting laser according to a first embodiment of the present technology.

FIG. 2 is a plan view of first and second confinement portions of the surface emitting laser of FIG. 1.

FIG. 3 is a flowchart for describing a method for manufacturing the surface emitting laser of FIGS. 1 and 37.

FIG. 4 is a cross-sectional view for describing a first process (first stacked body generation processing) in FIG. 3.

FIG. 5 is a flowchart for describing a second stacked body generation processing 1 as an example of a second process (second stacked body generation processing) in FIG. 3.

FIG. 6 is a cross-sectional view illustrating a first process in FIG. 5.

FIG. 7 is a cross-sectional view illustrating a second process in FIG. 5.

FIG. 8 is a cross-sectional view illustrating a third process in FIG. 5.

FIG. 9 is a cross-sectional view illustrating a fourth process in FIG. 5.

FIG. 10 is a cross-sectional view (before joining) illustrating a third process in FIG. 3.

FIG. 11 is a cross-sectional view (after joining) illustrating the third process in FIG. 3.

FIG. 12 is a cross-sectional view illustrating a fourth process in FIG. 3.

FIG. 13 is a cross-sectional view illustrating a fifth process in FIG. 3.

FIG. 14 is a cross-sectional view illustrating a sixth process in FIG. 3.

FIG. 15 is a cross-sectional view illustrating a seventh process in FIG. 3.

FIG. 16 is a cross-sectional view illustrating an eighth process in FIG. 3.

FIG. 17 is a cross-sectional view illustrating a ninth process in FIG. 3.

FIG. 18 is a cross-sectional view illustrated a 10th process in FIG. 3.

FIG. 19 is a cross-sectional view illustrated a 11th process in FIG. 3.

FIG. 20 is a cross-sectional view illustrating a configuration of a surface emitting laser according to Modification 1 of the first embodiment of the present technology.

FIG. 21 is a cross-sectional view illustrating a configuration of a surface emitting laser according to Modification 2 of the first embodiment of the present technology.

FIG. 22 is a cross-sectional view illustrating a configuration of a surface emitting laser according to Modification 3 of the first embodiment of the present technology.

FIG. 23 is a cross-sectional view illustrating a configuration of a surface emitting laser according to Modification 4 of the first embodiment of the present technology.

FIG. 24 is a cross-sectional view illustrating a configuration of a surface emitting laser according to Modification 5 of the first embodiment of the present technology.

FIG. 25 is a cross-sectional view illustrating a configuration of a surface emitting laser according to Modification 6 of the first embodiment of the present technology.

FIG. 26 is a cross-sectional view illustrating a configuration of a surface emitting laser according to Modification 7 of the first embodiment of the present technology.

FIG. 27 is a cross-sectional view illustrating a configuration of a surface emitting laser according to Modification 8 of the first embodiment of the present technology.

FIG. 28 is a cross-sectional view illustrating a configuration of a surface emitting laser according to Modification 9 of the first embodiment of the present technology.

FIG. 29 is a cross-sectional view illustrating a configuration of a surface emitting laser according to Modification 10 of the first embodiment of the present technology.

FIG. 30 is a cross-sectional view illustrating a configuration of a surface emitting laser according to Modification 11 of the first embodiment of the present technology.

FIG. 31 is a cross-sectional view illustrating a configuration of a surface emitting laser according to Modification 12 of the first embodiment of the present technology.

FIG. 32 is a cross-sectional view illustrating a configuration of a surface emitting laser according to Modification 13 of the first embodiment of the present technology.

FIG. 33 is a cross-sectional view illustrating a configuration of a surface emitting laser according to Modification 14 of the first embodiment of the present technology.

FIG. 34 is a cross-sectional view illustrating a configuration of a surface emitting laser according to Modification 15 of the first embodiment of the present technology.

FIG. 35 is a cross-sectional view illustrating a configuration of a surface emitting laser according to a second embodiment of the present technology.

FIG. 36 is a cross-sectional view illustrating a configuration of a surface emitting laser according to a third embodiment of the present technology.

FIG. 37 is a cross-sectional view illustrating a configuration of a surface emitting laser according to a fourth embodiment of the present technology.

FIG. 38 is a flowchart for describing second stacked body generation processing 2 as an example of the second process in FIG. 3.

FIG. 39 is a cross-sectional view illustrating a first process in FIG. 38.

FIG. 40 is a cross-sectional view illustrating a second process in FIG. 38.

FIG. 41 is a cross-sectional view illustrating a third process in FIG. 38.

FIG. 42 is a cross-sectional view (before joining) illustrating the third process in FIG. 3.

FIG. 43 is a cross-sectional view (after joining) illustrating the third process in FIG. 3.

FIG. 44 is a cross-sectional view illustrating the fourth process in FIG. 3.

FIG. 45 is a cross-sectional view illustrating the fifth process in FIG. 3.

FIG. 46 is a cross-sectional view illustrating the sixth process in FIG. 3.

FIG. 47 is a cross-sectional view illustrating the seventh process in FIG. 3.

FIG. 48 is a cross-sectional view illustrating the eighth process in FIG. 3.

FIG. 49 is a cross-sectional view illustrating the ninth process in FIG. 3.

FIG. 50 is a cross-sectional view illustrated the 10th process in FIG. 3.

FIG. 51 is a cross-sectional view illustrated the 11th process in FIG. 3.

FIG. 52 is a cross-sectional view illustrating a configuration of a surface emitting laser according to Modification 1 of the fourth embodiment of the present technology.

FIG. 53 is a cross-sectional view illustrating a configuration of a surface emitting laser according to Modification 2 of the fourth embodiment of the present technology.

FIG. 54 is a cross-sectional view illustrating a configuration of a surface emitting laser according to Modification 3 of the fourth embodiment of the present technology.

FIG. 55 is a cross-sectional view illustrating a configuration of a surface emitting laser according to Modification 4 of the fourth embodiment of the present technology.

FIG. 56 is a plan view illustrating a configuration example of a surface emitting laser to which the present technology can be applied.

FIG. 57A is a cross-sectional view taken along line X-X of FIG. 56. FIG. 57B is a cross-sectional view taken along line Y-Y in FIG. 56.

FIG. 58 is a diagram illustrating an application example of a surface emitting laser according to each embodiment of the present technology and its modification to a distance measuring device.

FIG. 59 is a block diagram illustrating an example of a schematic configuration of a vehicle control system.

FIG. 60 is an explanatory view illustrating an example of an installation position of the distance measuring device.

### MODE FOR CARRYING OUT THE INVENTION

Hereinafter, preferred embodiments of the present technology will be described in detail with reference to the accompanying drawings. Note that in the description and the drawings, components having substantially the same functional configuration are denoted by the same reference numerals, and redundant descriptions are omitted. The embodiments described below illustrate representative embodiments of the present technology, and the scope of the present technology is not narrowly interpreted by these embodiments. In the present description, even in a case where it is described that a surface emitting laser according to the present technology exhibits a plurality of effects, it is sufficient if the surface emitting laser according to the present technology exhibits at least one effect. The effects described herein are merely examples and are not limited, and other effects may be provided.

Furthermore, description will be given in the following order.
1. Introduction
2. Surface Emitting Laser According to First Embodiment of Present Technology
   (1) Configuration of Surface Emitting Laser
   (2) Operation of Surface Emitting Laser
   (3) Method for Manufacturing Surface Emitting Laser
   (4) Effects of Surface Emitting Laser and Method for Manufacturing the Same
3. Surface Emitting Lasers According to Modifications 1 to 15 of First Embodiment of Present Technology
4. Surface Emitting Laser According to Second Embodiment of Present Technology
5. Surface Emitting Laser According to Third Embodiment of Present Technology
6. Surface Emitting Laser According to Fourth Embodiment of Present Technology
   (1) Configuration of Surface Emitting Laser
   (2) Operation of Surface Emitting Laser
   (3) Method for Manufacturing Surface Emitting Laser
   (4) Effects of Surface Emitting Laser and Method for Manufacturing the Same
7. Surface Emitting Lasers According to Modifications 1 to 4 of Fourth Embodiment of Present Technology
8. Configuration Example of Surface Emitting Laser to Which Present Technology Can Be Applied
9. Modification Example of Present Technology
10. Application Example to Electronic Device
11. Example in Which Surface Emitting Laser Is Applied to Distance Measuring Device
12. Example in Which Distance Measuring Device Is Mounted on Mobile Body

1. Introduction

In recent years, a vertical cavity surface emitting laser (VCSEL) has been used in a wide range of fields such as a retina direct drawing device and a face authentication sensor, but further improvement in efficiency and a high yield during mass production are demanded. In order to achieve a highly efficient VCSEL, it is effective to confine (narrow) light and current in the confinement portion (narrow portion). In this case, since the confinement diameter (narrowed diameter) greatly affects the characteristics of the VCSEL, it is necessary to control with high accuracy particularly at the time of VCSEL mass production. For example, in a VCSEL using an AlGaAs-based compound semiconductor, an oxidation confinement structure in which AlAs is converted to AlOx by water vapor oxidation is mainly used, but since the rate of water vapor oxidation changes in a wafer plane and in each batch, there is a problem that the yield is deteriorated. Accordingly, development of a surface emitting laser capable of generating a structure that confines light and current with excellent controllability and improving the yield has been expected.

2. Surface Emitting Laser According to First Embodiment of Present Technology

(1) Configuration of Surface Emitting Laser

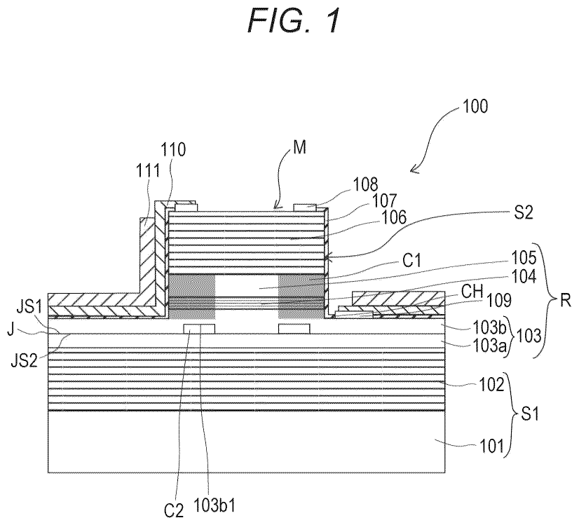

FIG. 1 is a cross-sectional view illustrating a configuration of a surface emitting laser 100 according to a first embodiment of the present technology. Hereinafter, for the sake of convenience, the upper part in the cross-sectional view of FIG. 1 and the like will be described as an upper side, and the lower part in the cross-sectional view of FIG. 1 and the like will be described as a lower side.

As an example, as illustrated in FIG. 1, the surface emitting laser 100 includes a first structure S1 including a substrate 101 and a first multilayer film reflector 102, a second structure S2 including a second multilayer film reflector 106, and a resonator R including an active layer 104 disposed between the first and second structures S1 and S2. The surface emitting laser 100 is driven by, for example, a laser driver.

In the surface emitting laser 100, as an example, the first multilayer film reflector 102, the resonator R, and the second multilayer film reflector 106 are stacked on the substrate 101 in this order from the substrate 101 side.

As an example, a mesa M including the resonator R (excluding, however, a lower portion of a second constituent layer 103b of a first cladding layer 103 to be described later) and a second multilayer film reflector 106 is formed on the substrate 101. The mesa M has, for example, a substantially cylindrical shape, but may have another shape such as a substantially elliptical columnar shape, a polygonal columnar shape, a truncated cone shape, an elliptical frustum shape, or a polygonal frustum shape. The height direction of the mesa M substantially coincides with a stacking direction (vertical direction) of each of the constituent layers of the surface emitting laser 100.

As an example, the surface emitting laser 100 emits light from the top of the mesa M. That is, as an example, the surface emitting laser 100 is a front surface emitting type surface emitting laser.

[First Structure]

(Substrate)

As an example, the substrate 101 is a semiconductor substrate (for example, a GaAs substrate) of a first conductivity type (for example, n-type).

(First Multilayer Film Reflector)

As an example, the first multilayer film reflector 102 is disposed on the substrate 101.

As an example, the first multilayer film reflector 102 is a semiconductor multilayer film reflector. The multilayer film reflector is also referred to as a distributed Bragg reflector. A semiconductor multilayer film reflector which is a type of multilayer film reflector (the distributed Bragg reflector) has low light absorption, high reflectance, conductivity, and insulating property.

More specifically, as an example, the first multilayer film reflector 102 is a semiconductor multilayer film reflector of a first conductivity type (for example, n-type), and has a structure in which a plurality of types (for example, two types) of semiconductor layers having different refractive indexes is alternately layered with an optical thickness of a ¼ wavelength of an oscillation wavelength. Each refractive index layer of the first multilayer film reflector 102 is formed by an AlGaAs-based compound semiconductor of the first conductivity type (for example, n-type). The reflectance of the first multilayer film reflector 102 is set slightly higher than that of the second multilayer film reflector 106.

[Second Structure]

(Second Multilayer Film Reflector 106)

As an example, the second multilayer film reflector 106 is disposed on the resonator R.

The second multilayer film reflector 106 is, for example, a semiconductor multilayer film reflector. The multilayer film reflector is also referred to as a distributed Bragg reflector. A semiconductor multilayer film reflector which is a type of multilayer film reflector (the distributed Bragg reflector) has low light absorption, high reflectance, and conductivity.

More specifically, as an example, the second multilayer film reflector 106 is a semiconductor multilayer film reflector of a second conductivity type (for example, p-type), and has a structure in which a plurality of types (for example, two types) of semiconductor layers having different refractive indexes is alternately stacked with an optical thickness of ¼ wavelength of the oscillation wavelength. Each refractive index layer of the second multilayer film reflector 106 is formed by an AlGaAs-based compound semiconductor of the second conductivity type (for example, p-type).

[Resonator]

As an example, the resonator R includes, in addition to the active layer 104, first and second cladding layers 103 and 105 disposed at positions sandwiching the active layer 104.

(Active layer)

As an example, the active layer 104 has a quantum well structure including a barrier layer including an AlGaAs-based compound semiconductor and a quantum well layer. This quantum well structure may be a single quantum well structure (QW structure) or a multiple quantum well structure (MQW structure).

(First cladding layer)

The first cladding layer 103 is formed by, for example, a first conductivity type (for example, n-type) AlGaAs-based compound semiconductor.

Here, a joint portion J exists in the resonator R. As an example, the joint portion J exists inside the first cladding layer 103. More specifically, the first cladding layer 103 includes first and second constituent layers 103a and 103b joined to each other. As an example, the first constituent layer 103a is on a lower side (substrate 101 side) of the first constituent layer 103b.

Here, in the present description, the joint portion J includes at least one of a first joint surface that is a joint surface of a first constituent portion with a second constituent portion of the first and second constituent portions joined to each other of the surface emitting laser, a second joint surface that is a joint surface of the second constituent portion with the first constituent portion, or an interface (joint interface) between the first and second joint surfaces.

Hereinafter, some examples will be given as a joining method in the joint portion J.

Surface-Activated Bonding

Bonding can be performed at room temperature or even in a case of heating. In this method, an outermost surface of each of two substrates to be joined is treated with an ion beam or plasma, an activated state in which a dangling bond is present in an outermost surface atom is obtained, and the substrates are joined by pressure bonding. The crystallinity of the outermost surface of the substrate to which ions are applied disappears, and a portion of several nm from the joint interface becomes an amorphous layer. The amorphous layer may contain metal elements (for example, by ion gun irradiation). However, the amorphous layer may be recrystallized by performing a heat treatment.

Atomic Diffusion Bonding

This is a method of sputtering a metal (for example, Ti) of several nm on the outermost surfaces of two substrates to be joined, and then joining wafers at room temperature by utilizing the fact that the surface energy of metal and the grain boundary or surface atom diffusion coefficient of a microcrystalline thin film are much larger than those in the crystal. A sputtered metal film remains at the joint interface. However, in a case where SiO₂ is used as a Ti base film, when subjected to a heat treatment after bonding, TiOx is obtained, and the transmittance at the joint interface becomes 100%. At this time, Ti oxide (amorphous) of several nm is present at the joint interface.

Plasma Activated Junction

In this method, an OH group is attached to the outermost surface of each of two substrates to be joined plasma treatment, the substrates are overlapped and joined, and the OH group is removed and joining is performed by heat treatment. Basically, SiO₂ is attached to the outermost surface of each substrate, and the above processing is performed on the SiO₂. Some voids are generated at the joint interface during annealing to remove the OH group.

Bonding with Adhesive

In this method, an adhesive is applied to at least one surface of two substrates to be joined, and the substrates are joined to each other by intermolecular force and physical/chemical bonding. The applied adhesive remains on the joint interface.

(Second Cladding Layer)

The second cladding layer 105 is formed by, for example, a second conductivity type (for example, p-type) AlGaAs-based compound semiconductor.

At least a part of a central portion of the resonator R in a thickness direction (length direction, stacking direction, height direction of the mesa M, or vertical direction) is surrounded by, for example, a first confinement portion C1 that confines a current and a second confinement portion C2 that confines at least the light of the current or the light. Here, in plan view, a central portion of the resonator R coincides with a central portion of the mesa M, and a peripheral portion of the resonator R (a portion existing around the central portion of the resonator R) coincides with a peripheral portion of the mesa M.

As an example, the first and second confinement portions C1 and C2 surround different portions of the resonator R in the thickness direction. For example, the first confinement portion C1 surrounds the entire region in the thickness direction of a central portion of the active layer 104, a part (upper portion) of the central portion of the first cladding layer 103 in the thickness direction, and the entire region in the thickness direction of a central portion of the second cladding layer 105. For example, the second confinement portion C2 surrounds another portion (lower portion) in the thickness direction of the central portion of the first cladding layer 103.

(First Confinement Portion)

As an example, the first confinement portion C1 (gray region in FIG. 1) functions as a current confinement portion (current constriction portion) that confines (constricts) the current injected into the active layer 104.

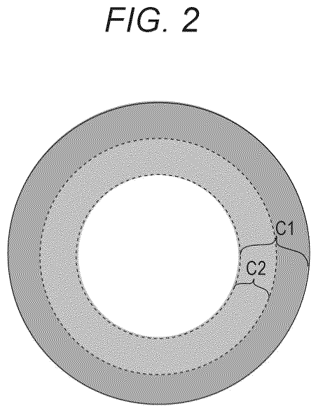

As an example, the first confinement portion C1 has a frame shape (circling shape) such as an annular shape in plan view (see FIG. 2).

As an example, the first confinement portion C1 is provided at a position other than the joint portion J, for example, at a position slightly away from the joint portion J.

More specifically, the first confinement portion C1 is provided in a region that does not include a second joint surface JS2, which is a joint surface of the second constituent portion with the first constituent portion, of the second constituent portion of the first constituent portion on one side (for example, the lower side) and the second constituent portion on the other side (for example, the upper side) of the joint portion J. Here, the first constituent portion includes at least the first constituent layer 103a among the substrate 101, the first multilayer film reflector 102, and the first constituent layer 103a of the first cladding layer 103. The second constituent portion includes at least the second constituent layer 103b among the second constituent layer 103b of the first cladding layer 103, the active layer 104, the second cladding layer 105, and the second multilayer film reflector 106.

More specifically, the first confinement portion C1 is provided across a peripheral portion of the second cladding layer 105, a peripheral portion of the active layer 104, and a peripheral portion of the upper portion (portion on the active layer 104 side) of the second constituent layer 103b of the first cladding layer 103.

In the first confinement portion C1, the peripheral portion of the second cladding layer 105, the peripheral portion of the active layer 104, and the upper portion of the second constituent layer 103b of the first cladding layer 103 are arranged in this order from an upstream side to a downstream side of a current passage from an anode electrode 108 to a cathode electrode 109 described later via the active layer 104. Therefore, the contribution to current confinement in the active layer 104 is the highest in the peripheral portion of the second cladding layer 105, is the next highest in the peripheral portion of the active layer 104, and is the next highest to this peripheral portion in the peripheral portion of the first cladding layer 103.

The first confinement portion C1 has a higher electrical resistance than at least a part (for example, an upper portion of a central portion of the second constituent layer 103b of the first cladding layer 103, a central portion of the active layer 104, and a central portion of the second cladding layer 105, and the same applies hereinafter) of the central portion of the resonator R in the thickness direction surrounded by the first confinement portion C1. That is, the first confinement portion C1 is a high electric resistance layer provided so as to surround at least the part of the central portion of the resonator R in the thickness direction and having electric resistance higher than that of the at least a part.

For example, the first confinement portion C1 may be an ion implantation layer provided so as to surround at least the part of the central portion of the resonator R in the thickness direction surrounded by the first confinement portion C1.

For example, the first confinement portion C1 may be a layer (electric resistance adjustment layer) surrounded by the first confinement portion C1 and formed by a compound semiconductor having a band gap larger than at least the part of the central portion of the resonator R in the thickness direction. That is, the first confinement portion C1 may have a quantum well disordered (QWI) structure.

For example, the first confinement portion C1 may be a layer (electric resistance adjustment layer) that is provided so as to surround at least a part of the central portion of the resonator R in the thickness direction, into which impurities such as Zn are thermally diffused, for example.

For example, the first confinement portion C1 may be a layer that is provided so as to surround at least the part of the central portion of the resonator R in the thickness direction, into which ions are implanted, and into which impurities such as Zn are thermally diffused, for example.

For example, the first confinement portion C1 may have a quantum well disordered (QWI) structure provided so as to surround at least the part of the central portion of the resonator R in the thickness direction, and may be a layer into which ions are implanted and/or into which impurities such as Zn are diffused.

A thickness of the first confinement portion C1 in the stacking direction is, for example, 10 to 3000 nm.

(Second Confinement Portion)

The second confinement portion C2 confines at least light generated in the active layer 104 among the current injected into the active layer 104 and the light generated in the active layer 104.

As an example, the second confinement portion C2 is provided at the joint portion J or near the joint portion J.

More specifically, the second confinement portion C2 is provided on the second joint surface JS2, which is a joint surface of the second constituent portion with the first constituent portion, of the first constituent portion on one side (for example, the lower side) and the second constituent portion on the other side (for example, the upper side) of the joint portion J. Here, the first constituent portion includes at least the first constituent layer 103a among the substrate 101, the first multilayer film reflector 102, and the first constituent layer 103a of the first cladding layer 103. The second constituent portion includes at least the second constituent layer 103b among the second constituent layer 103b of the first cladding layer 103, the active layer 104, the second cladding layer 105, and the second multilayer film reflector 106.

More specifically, the second joint surface JS2 is provided with a recess 103b1 surrounding the part of the central portion of the resonator R in the thickness direction (for example, a lower portion of the central portion of the second constituent layer 103b of the first cladding layer 103). The second confinement portion C2 is a layer existing in the recess 103b1 (specifically, substantially the entire region in the recess 103b1).

The recess 103b1 and the second confinement portion C2 have a frame shape (circling shape) such as an annular shape in plan view (see FIG. 2). As an example, the recess 103b1 and the second confinement portion C2 partially overlap the first confinement portion C1 in plan view (see FIG. 2). In plan view, the center of the first confinement portion C1 and the center of the second confinement portion C2 may coincide with each other or may deviate from each other. In plan view, the inner diameter of the first confinement portion C1 and the inner diameter of the second confinement portion C2 may be the same or different. As an example, the recess 103b1 and the second confinement portion C2 have an inner diameter of, for example, 0.5 to 300 μm, a depth of, for example, 1 to 500 nm, and a difference between the inner diameter and the outer diameter of 0.1 to 300 μm.

As an example, the second confinement portion C2 may be a low refractive index layer surrounded by the second confinement portion C2 and having a refractive index lower than that of at least the part of the central portion of the resonator R in the thickness direction (for example, the lower portion of the central portion of the second constituent layer 103b of the first cladding layer 103). In this case, the second confinement portion C2 functions as a light confinement portion (light confinement portion) that confines the light generated in the active layer 104.

Examples of the material of the low refractive index layer include insulating materials such as air, SiO₂, SIN, and AlN. In the example of FIG. 1, the material of the low refractive index layer is air.

The low refractive index layer may have higher electric resistance than at least the part of the central portion of the resonator R in the thickness direction (for example, the lower portion of the second constituent layer 103b of the first cladding layer 103) surrounded by the recess 103b1 (for example, it may be an insulating layer or a semi-insulating layer (for example, a semiconductor layer whose doping concentration is adjusted, and the same applies hereinafter)). In this case, the second confinement portion C2 also functions as a current confinement portion (current constriction portion) that confines (constricts) the current injected into the active layer 104. Note that the material of the low refractive index layer is not necessarily an insulating material, and may be, for example, a conductive material (for example, a semiconductor, a metal, or the like).

As an example, the second confinement portion C2 may be a layer (for example, a semi-insulating layer, an insulating layer, or the like) having a higher refractive index and a higher electric resistance than at least the part of the central portion of the resonator R in the thickness direction (for example, the lower portion of the central portion of the second constituent layer 103b of the first cladding layer 103) surrounded by the second confinement portion C2.

The mesa M is covered with an insulating film 107 except for a part thereof. The insulating film 107 is formed by a dielectric such as SiO₂, SiN, or SiON. A film thickness of the insulating film 107 is, for example, 10 to 300 nm.

On the insulating film 107 on the top of the mesa M (for example, an upper surface of the second multilayer film reflector 106), for example, the anode electrode 108 having a frame shape in plan view (for example, a ring shape in plan view) is provided so as to be in contact with the top of the mesa M. As an example, the anode electrode 108 is disposed on the top of the mesa M such that the center substantially coincides with the center of the mesa M in plan view. An inner diameter side of the anode electrode 108 is an emission port of the laser beam. On an emission surface (for example, an upper surface of the second multilayer film reflector 106) that is a bottom surface of the emission port, a thin film which does not absorb or hardly absorbs emitted light of the surface emitting laser 100 (light having an oscillation wavelength of the surface emitting laser 100) is formed as an AR coating film.

As an example, the anode electrode 108 has a stacked structure in which a Ti layer, a Pt layer, and an Au layer are stacked in this order from the substrate 101 side. A film thickness of the Ti layer is, for example, 2 to 100 nm. A film thickness of the Pt layer is, for example, 2 to 300 nm. A film thickness of the Au layer is, for example, 100 to 500 nm. The anode electrode 108 is electrically connected to, for example, an anode (positive electrode) of the laser driver.

A stacked wiring is provided on a side surface on one side of the mesa M and the peripheral insulating film 107. The stacked wiring includes a pad wiring 110 constituting a lower layer and a plated wiring 111 constituting an upper layer, which are stacked with each other.

The pad wiring 110 is disposed so as to cover a periphery on one side, the side surface, and a corner portion between the side surface and the upper surface of the mesa M, and a portion covering the corner portion is in contact with the anode electrode 108. An end position of the pad wiring 110 on the mesa M is located outside the inner diameter position of the anode electrode 108 by, for example, about 1 to 200 μm. Thus, absorption of the emitted light (laser light) by the pad wiring 110 can be suppressed.

As an example, the pad wiring 110 has a stacked structure in which a Ti layer, a Pt layer, and an Au layer are stacked in this order from the substrate 101 side. A film thickness of the Ti layer is, for example, 2 to 100 nm. A film thickness of the Pt layer is, for example, 2 to 300 nm. A film thickness of the Au layer is, for example, 100 to 1000 nm.

The pad wiring 110 may have another configuration as long as it is electrically connected to the laser driver, for example, when the surface emitting laser 100 is mounted.

The plated wiring 111 is formed by an Au layer, for example. A film thickness of the Au layer is, for example, 1000 to 5000 nm. The plated wiring 111 may have another configuration as long as the pad wiring 110 can be substantially thickened to reduce resistance.

A contact hole CH is formed in the insulating film 107 on the periphery on the other side of the mesa M (for example, the second constituent layer 103b of the first cladding layer 103), and the cathode electrode 109 is provided in the contact hole CH so as to be in contact with the second constituent layer 103b of the first cladding layer 103.

As an example, the cathode electrode 109 has substantially the same configuration as the anode electrode 108. As an example, a pad wiring substantially the same as the pad wiring 110 is stacked on the cathode electrode 109 so as to be in contact with the cathode electrode 109, and a plated wiring substantially the same as the plated wiring 111 is stacked on the pad wiring. The cathode electrode 109 is electrically connected to, for example, a cathode (negative electrode) of the laser driver.

Here, in the second constituent layer 103b of the first cladding layer 103, a current path exists between the first and second confinement portions C1 and C2, and this current path is a part of a current passage from the anode electrode 108 to the cathode electrode 109 via the active layer 104. That is, the high electric resistance region and the insulating region do not exist on the current passage. Thus, a current can efficiently flow from the anode electrode 108 to the cathode electrode 109. Furthermore, by the current path, it is possible to suppress a current from flowing through the joint interface (interface between the first constituent layer 103a and the second constituent layer 103b of the first cladding layer 103), and it is possible to suppress a decrease in reliability.

(2) Operation of Surface Emitting Laser

In the surface emitting laser 100, for example, the current supplied from the anode side of the laser driver and flowing in from the anode electrode 108 passes through the second multilayer film reflector 106, is narrowed at the first confinement portion C1, and is injected into the active layer 104, and the active layer 104 emits light. The current passing through the active layer 104 passes through the current path in the second constituent layer 103b of the first cladding layer 103, reaches the cathode electrode 109, and flows out from the cathode electrode 109 to, for example, the cathode side of the laser driver. The light generated in the active layer 104 reciprocates between the first and second multilayer film reflectors 102 and 106, is confined in the second confinement portion C2 during the reciprocation, is amplified in the active layer 104, and is emitted as laser light from the top of the mesa M when an oscillation condition is satisfied.

(3) Method for Manufacturing Surface Emitting Laser

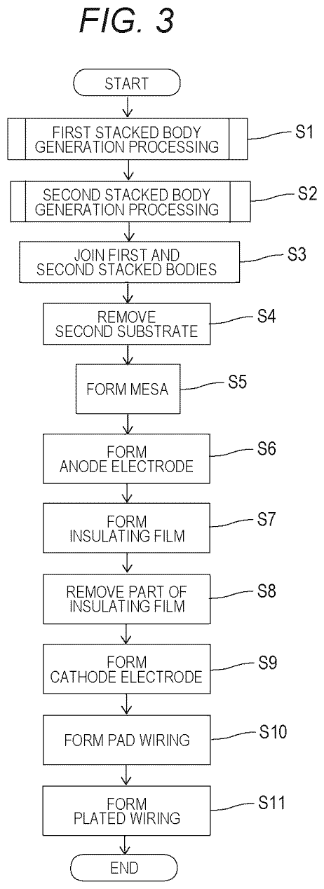

Hereinafter, a method for manufacturing the surface emitting laser 100 will be described with reference to a flowchart (steps S1 to S11) of FIG. 3. As an example, the surface emitting laser 100 is manufactured by a semiconductor manufacturing method using a semiconductor manufacturing apparatus.

<Step S1>

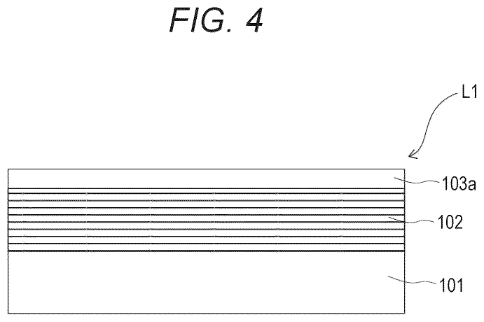

In step S1, a first stacked body generation processing is performed. In the first stacked body generation processing, as an example, the first multilayer film reflector 102 and the first constituent layer 103a of the first cladding layer 103 are stacked (for example, epitaxially grown at a growth temperature of 605° C.) on the substrate 101 (hereinafter also referred to as the “first substrate 101”) in a growth chamber by a chemical vapor deposition (CVD) method, for example, a metal organic chemical vapor deposition (MOCVD) method to generate a first stacked body L1 (see FIG. 4).

Note that, when the MOCVD is performed, for example, trimethylgallium ((CH₃)₃Ga) is used as a source gas of gallium, for example, trimethylaluminum ((CH₃)₃Al) is used as a source gas of aluminum, for example, trimethylindium ((CH₃)₃In) is used as a source gas of indium, and for example, trimethylarsenic (((CH₃)₃As) is used as a source gas of As. Furthermore, as a source gas of silicon, for example, monosilane (SiH₄) is used, and as a source gas of carbon, for example, carbon tetrabromide (CBr₄) is used.

<Step S2>

In step S2, a second stacked body generation processing is performed.

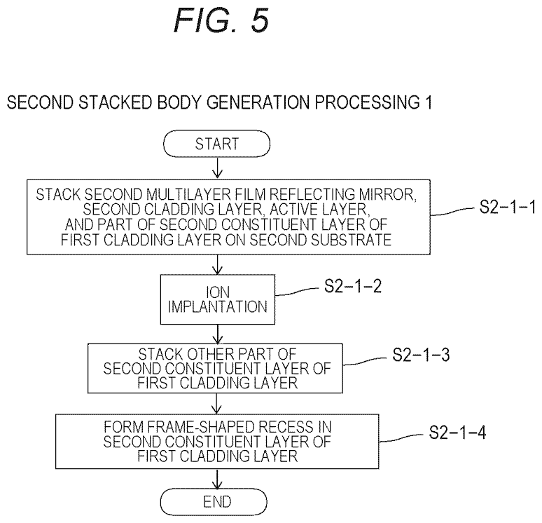

Hereinafter, a second stacked body generation processing 1 as an example of the second stacked body generation processing performed to manufacture the surface emitting laser 100 will be described with reference to a flowchart of FIG. 5.

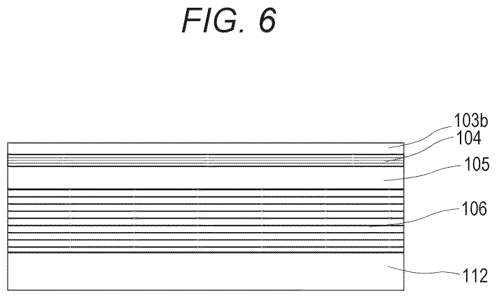

In step S2-1-1, as an example, the second multilayer film reflector 106, the second cladding layer 105, the active layer 104, and a part of the second constituent layer 103b of the first cladding layer 103 in the thickness direction are stacked (for example, epitaxially grown at a growth temperature of 605° C.) on the second substrate 112 in the growth chamber by the chemical vapor deposition (CVD) method, for example, the metal organic chemical vapor deposition (MOCVD) method described above to generate a stacked body (see FIG. 6).

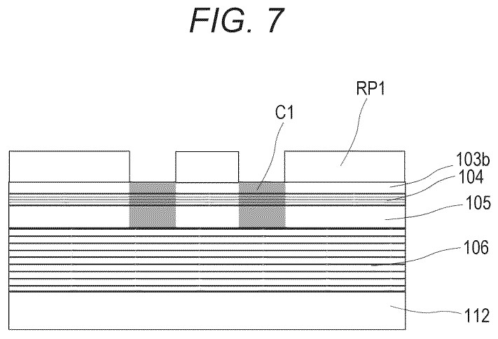

In step S2-1-2, ion implantation is performed (see FIG. 7). Specifically, a resist pattern RP1 opened only at a portion where the recess 103b1 is to be formed is formed on a part of the second constituent layer 103b of the second cladding layer 103 of the stacked body of FIG. 6 in the thickness direction, and ion implantation is performed using the resist pattern RP1 as a mask. Here, the ion-implanted region (region where ions exist) formed by the ion implantation extends, for example, across at least a part of the second constituent layer 103b of the first cladding layer 103 in the thickness direction, the entire region of the active layer 104 in the thickness direction, and the entire region of the second cladding layer 105 in the thickness direction.

By executing step S2-1-2, the first confinement portion C1 is formed.

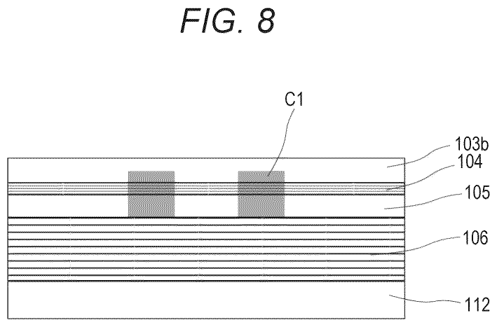

In step S2-1-3, the other part (remaining part) of the second constituent layer 103b of the first cladding layer 103 is stacked on a part of the second constituent layer 103b (see FIG. 8). Specifically, the second constituent layer 103b is epitaxially grown (regrown) again, for example, at a growth temperature of 605° C. by, for example, the MOCVD method described above.

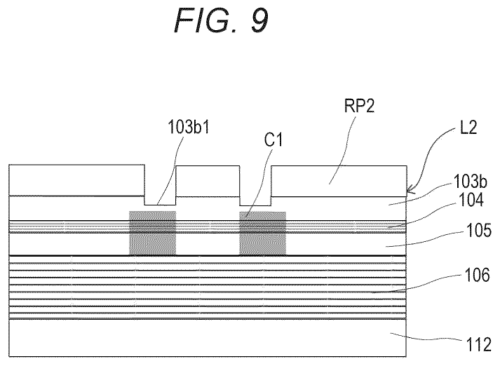

In step S2-1-4, the frame-shaped recess 103b1 (circular-shaped recess) is formed in the second constituent layer 103b of the first cladding layer 103 (see FIG. 9). Specifically, a resist pattern RP2 having a frame-shaped opening for forming the recess 103b1 is formed on the second constituent layer 103b. Next, using the resist pattern RP2 as a mask, at least a part of a regrowth layer, which is the other part of the second constituent layer 103b, is removed by etching, for example, by wet etching to form a frame-shaped recess 103b1. Thereafter, the resist pattern RP2 is removed. At this time, the inside of the recess 103b1 is an air layer. Thereafter, the above-described semi-insulating material or insulating material is embedded in the recess 103b1 as necessary. As a result, the second confinement portion C2 is formed, and a stacked body L2 is obtained.

<Step S3>

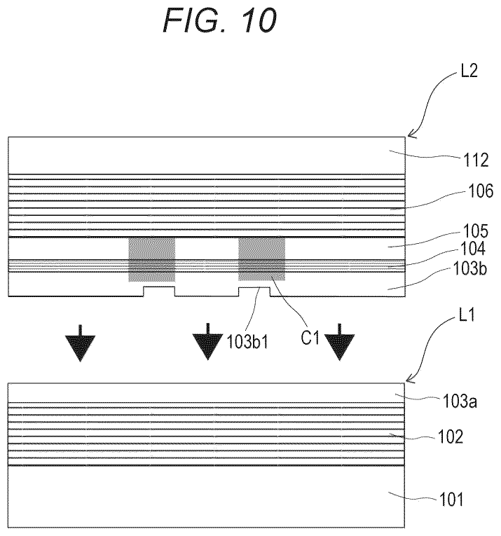

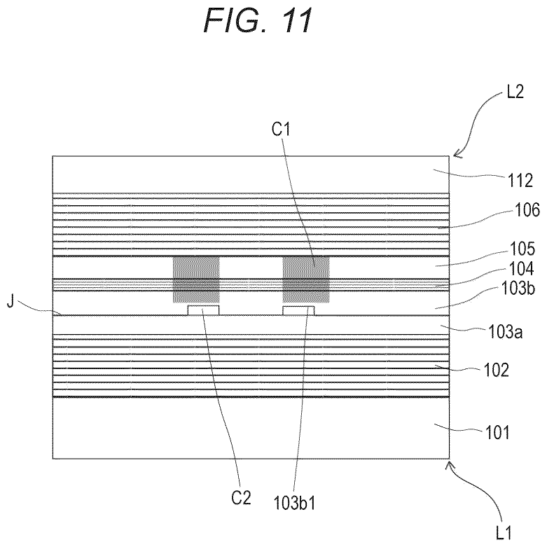

In step S3, the first and second stacked bodies L1 and L2 are joined (see FIGS. 10 and 11). Specifically, for example, the first constituent layer 103a of the first cladding layer 103 of the first stacked body L1 and the second constituent layer 103b of the first cladding layer 103 of the second stacked body L2 are joined using any one of the above-described joining methods (1) to (4).

<Step S4>

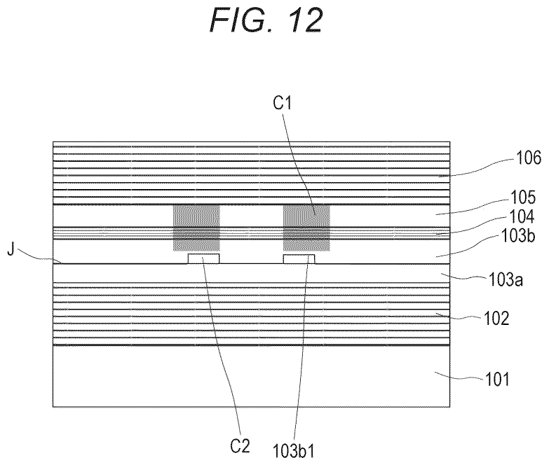

In step S4, the second substrate 112 is removed (see FIG. 12). Specifically, after the second substrate 112 is thinned by grinding, the thinned second substrate 112 is removed by wet etching. As a result, the surface of the second multilayer film reflector 106 is exposed.

<Step S5>

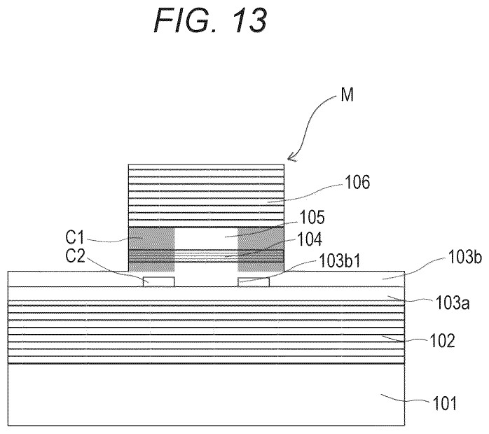

In step S5, the mesa M is formed (see FIG. 13). Specifically, as an example, upper portions of the second multilayer film reflector 106, the second cladding layer 105, the active layer 104, and the second constituent layer 103b of the first cladding layer 103 are etched to form the mesa M.

More specifically, a resist pattern for forming the mesa M is generated on the second multilayer film reflector 106 by photolithography. Next, using this resist pattern as a mask, the stacked body obtained by executing step S4 is etched until the second constituent layer 103b of the first cladding layer 103 is exposed (for example, until the side surface of the active layer 104 is completely exposed) by, for example, reactive ion etching (RIE etching) to form the mesa M having an outer diameter longer than the outer diameter of the recess 103b1 by 1 to 40 μm, for example. The etching here is performed until the etching bottom surface is located in the second constituent layer 103b of the first cladding layer 103. Thereafter, the resist pattern is removed.

<Step S6>

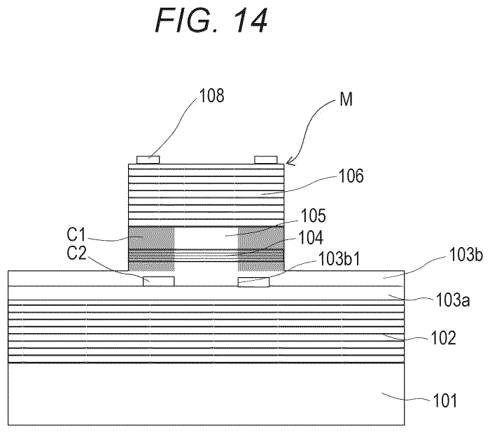

In step S6, the anode electrode 108 is formed (see FIG. 14). The anode electrode 108 can be formed by, for example, a lift-off method. In step S6, the frame-shaped (for example, annular) anode electrode 108 is formed on the second multilayer film reflector 106 by using, for example, a vacuum deposition method, a sputtering method, or the like. More specifically, the anode electrode 108 is formed so as to have an inner diameter longer than the inner diameter of the recess 103b1 by about 1 to 200 μm and an outer diameter shorter than the diameter of the mesa M by 1 to 200 μm.

<Step S7>

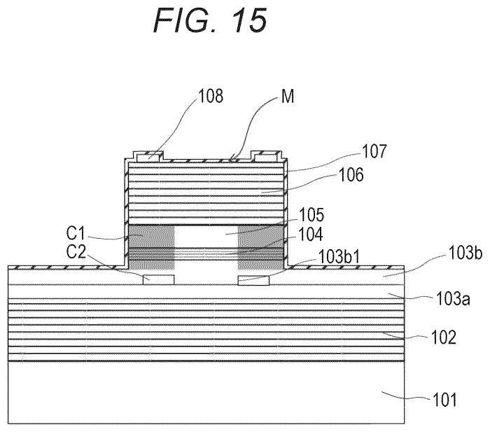

An insulating film 107 is formed (see FIG. 15). Specifically, the insulating film 107 is formed on the mesa M and its peripheral region by, for example, a CVD method, a vacuum vapor deposition method, a sputtering method, or the like.

<Step S8>

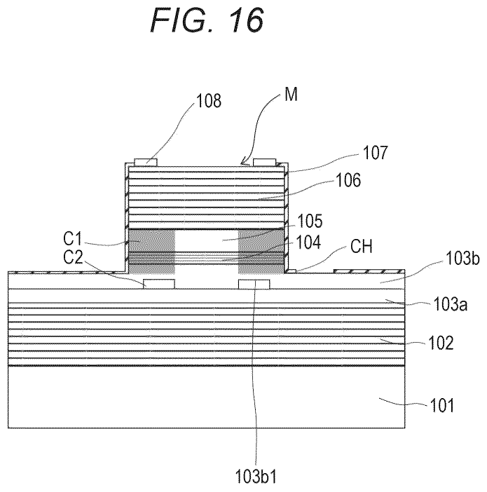

In step S8, a part of the insulating film 107 is removed (see FIG. 16). Specifically, for example, the insulating film 107 on the anode electrode 108 is removed by the RIE method or a solution containing hydrogen fluoride, and a part of the insulating film 107 covering the periphery of the mesa M (for example, the second constituent layer 103b of the second cladding layer 103) is removed by etching. As a result, the anode electrode 108 is exposed, the contact hole CH is formed on the second constituent layer 103b of the second cladding layer 103, and the second constituent layer 103b of the first cladding layer 103 is exposed through the contact hole CH.

<Step S9>

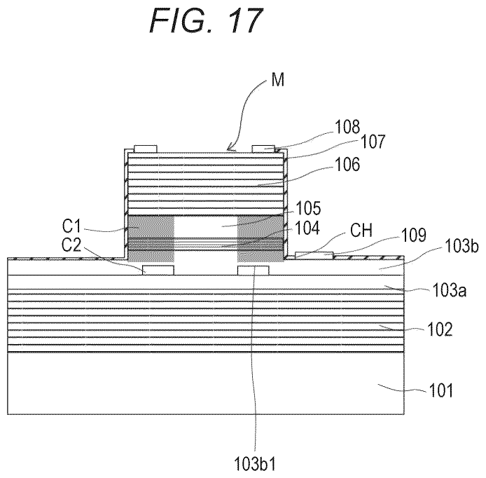

In step S9, the cathode electrode 109 is formed (see FIG. 17). Specifically, the cathode electrode 109 is formed in the contact hole CH so as to be in contact with the second constituent layer 103b of the first cladding layer 103.

<Step S10>

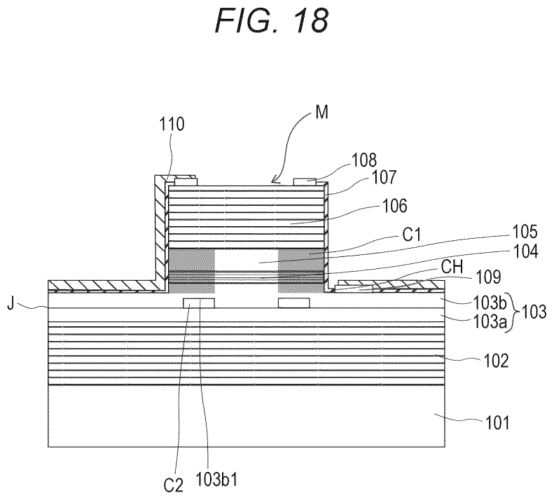

In step S10, the pad wiring 110 is formed (see FIG. 18). The pad wiring 110 can be formed by, for example, a lift-off method.

<Step S11>

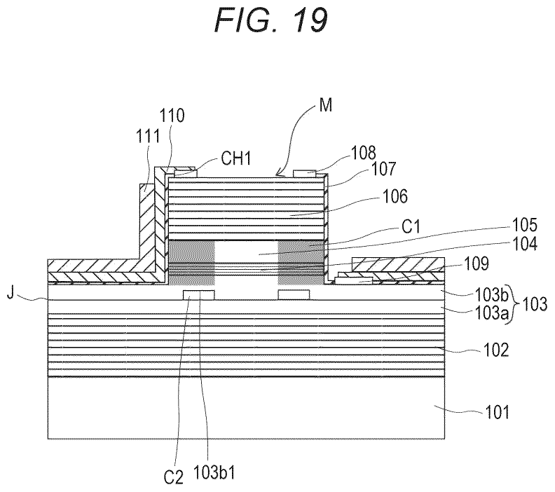

In step S11, the plated wiring 111 is formed (see FIG. 19). Specifically, the plated wiring 111 is formed so as to extend over the pad wiring 110 formed on the side surface of the mesa M and the pad wiring 110 formed on the peripheral region of the mesa M by, for example, a plating method.

(4) Effects of Surface Emitting Laser and Method for Manufacturing the Same

The surface emitting laser 100 according to the first embodiment of the present technology includes the first structure S1 including the first multilayer film reflector 102, the second structure S2 including the second multilayer film reflector 106, and the resonator R disposed between the first and second structures S1 and S2 and including the active layer 104, in which the joint portion J exists in at least one (for example, in the resonator R) of inside the first structure S1, inside the second structure S2, inside the resonator R, between the resonator R and the first structure S1, or between the resonator R and the second structure S2, and the first confinement portion C1 that confines a current is provided in at least one (for example, the second constituent portion) of the first or second constituent portion joined at the joint portion J, and the second confinement portion C2 that confines at least light of current or light is provided in at least one of the first or second constituent portion (for example, the second constituent portion).

In this case, the first confinement portion C1 can be generated with excellent controllability in at least one (for example, the second constituent portion) of the first or second constituent portion, and the second confinement portion C2 can be generated with excellent controllability in at least one (for example, the second constituent portion) of the first or second constituent portion.

As a result, with the surface emitting laser 100, it is possible to provide a surface emitting laser that can be manufactured with an excellent yield and has a configuration of confining a current and light.

At least a part (for example, the entire region) of the central portion of the active layer 104 in the thickness direction is surrounded by the first confinement portion C1 that confines the current. Thus, current confinement in the active layer 104 can be more effectively performed.

The resonator R further includes the first and second cladding layers 103 and 105 disposed at positions sandwiching the active layer 104, and the entire region in the thickness direction of the central portion of the second cladding layer 105 located on the upstream side of the current passage with respect to the active layer 104 is surrounded by the first confinement portion C1 confining the current. Thus, current confinement in the active layer 104 can be more effectively performed.

The resonator R further includes the first and second cladding layers 103 and 105 disposed at positions sandwiching the active layer 104, and the part of the central portion of the first cladding layer 103 in the thickness direction is surrounded by the second confinement portion C2 that confines at least light. Thus, it is possible to effectively confine light to at least the active layer 104 in a region adjacent to the active layer 104 of the resonator R.

The resonator R further includes the first and second cladding layers 103 and 105 disposed at positions sandwiching the active layer 104, the entire region in the thickness direction of the central portion of the second cladding layer 105 is surrounded by the first confinement portion C1 confining a current, and the part of the central portion of the first cladding layer 103 in the thickness direction is surrounded by a second confinement portion C2 confining at least light. Thus, both current confinement in the active layer 104 and light confinement in the active layer 104 can be effectively performed.

The joint portion J exists in the resonator R. Thus, the confinement portion can be provided at a desired position in the resonator R. For example, the first confinement portion C1 can be provided at a position other than the joint portion J (a position slightly away from the joint portion J). For example, the second confinement portion C2 can be provided in the joint portion J.

The resonator R further includes the first and second cladding layers 103 and 105 disposed at positions sandwiching the active layer 104, and the joint portion J exists inside the first cladding layer 103. Thus, damage to the active layer 104 can be suppressed as compared with a case where the joint portion exists inside the active layer 104, between the active layer 104 and the first cladding layer 103, or between the active layer 104 and the second cladding layer 105.

The first cladding layer 103 includes the first and second constituent layers 103a and 103b joined to each other, and the second confinement portion C2 is provided on the second joint surface JS2 that is a joint surface of the first cladding layer 103 with the first constituent layer 103a of the second constituent layer 103b. In this case, as compared with a case where the second confinement portion C2 is provided on the first joint surface JS1 which is a joint surface of the first cladding layer 103 with the second constituent layer 103b of the first constituent layer 103a, at least light confinement to the active layer 104 can be performed at a position closer to the active layer 104.

The second confinement portion C2 is a layer existing in the recess 103b1 provided in the first cladding layer 103 so as to surround the part of the central portion of the resonator R in the thickness direction on the second joint surface JS2. The layer is preferably a low refractive index layer having a refractive index lower than that of the part of the central portion in the thickness direction. Consequently, the second confinement portion C2 can effectively function as at least the optical confinement portion. Since the recess 103b1 is generated by, for example, etching and thus has excellent controllability of the width and the depth, the second confinement portion C2 can be generated with excellent controllability, and the yield can be improved. Furthermore, by appropriately selecting the material to be used for the low refractive index layer in the recess 103b1, the degree of optical confinement can be adjusted, and mode control becomes possible.

Moreover, the low refractive index layer preferably has a semi-insulating property or an insulating property. Thus, the second confinement portion C2 can also function as a current confinement portion.

The first confinement portion C1 has a higher electrical resistance than the part of the central portion of the resonator R in the thickness direction surrounded by the first confinement portion C1. Accordingly, the first confinement portion C1 can effectively function as a current confinement portion.

The first confinement portion C1 may be an ion implantation layer provided so as to surround the part of the central portion of the resonator R in the thickness direction. Thus, the first confinement portion C1 as the current confinement portion can be generated with excellent controllability, and the yield can be improved.

The first confinement portion C1 may be formed by a compound semiconductor surrounded by the first confinement portion C1 and having a larger band gap than the part of the central portion of the resonator R in the thickness direction. Thus, the first confinement portion C1 as the current confinement portion can be generated with excellent controllability, and the yield can be improved.

The first confinement portion C1 exists in the resonator R in which the joint portion J exists. Thus, ion implantation, hole diffusion, thermal diffusion, and the like for generating the first confinement portion C1 can be performed on a part of the resonator R (for example, the second constituent layer 103b of the first cladding layer 103), so that the implantation depth and the diffusion depth can be reduced, and the first confinement portion C1 can be generated with excellent width controllability.

On the other hand, conventionally, in the VCSEL, as in the example of Japanese Patent Application Laid-Open No. 2013-229443, when the confinement portion is formed by a metal layer, light leaking from the confinement portion is absorbed by the metal layer, so that an increase in threshold current and an increase in calorific value occur, leading to deterioration of performance of the VCSEL.

A method for manufacturing a surface emitting laser 100 includes a process of stacking the first structure S1 including the first multilayer film reflector 102 and a first portion of the resonator R (for example, the first constituent layer 103a of the first cladding layer 103) in this order on the first substrate 101 to generate the first stacked body L1, a process of generating the second stacked body L2, and a process of joining the first and second stacked bodies L1 and L2, in which in the process of generating the second stacked body L2, the second structure S2 including the second multilayer film reflector 106 and a second portion of the resonator R (for example, a part of the second constituent layer 103b of the first cladding layer 103) are stacked in this order on the second substrate 112, and at least one of ion implantation, hole diffusion, or impurity diffusion is performed on the second portion of the resonator R to form a frame-shaped current confinement portion, a third portion of the resonator R (for example, the remaining portion of the second constituent layer 103b of the first cladding layer 103) is stacked on the second portion of the resonator R, the frame-shaped recess 103b1 is formed in the third portion of the resonator R, and in the joining process, the third portion of the resonator in the second stacked body L2 and the first portion of the resonator R in the first stacked body L1 are joined.

According to the method for manufacturing the surface emitting laser 100, a surface emitting laser having a structure for confining current and light can be manufactured with an excellent yield.

Moreover, according to the method for manufacturing the surface emitting laser 100, since current and/or light is confined in the active layer 104 and/or near the active layer 104, it is possible to manufacture the surface emitting laser 100 capable of effectively confining the current in the active layer and/or confining the light in the active layer.

3. Surface Emitting Lasers According to Modifications 1 to 15 of First Embodiment of Present Technology

Hereinafter, surface emitting lasers according to Modifications 1 to 15 of the first embodiment of the present technology will be described.

(Modification 1)

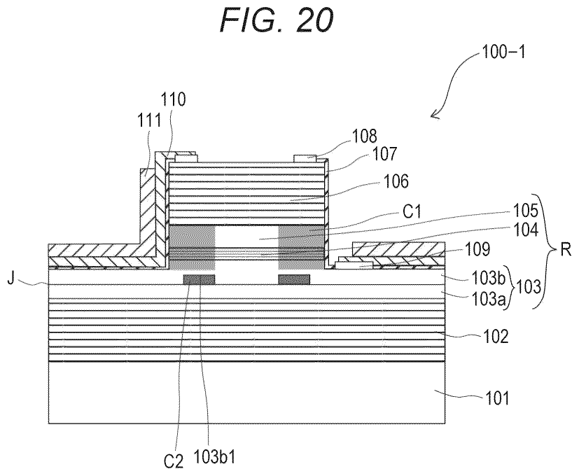

As illustrated in FIG. 20, a surface emitting laser 100-1 of Modification 1 has a configuration similar to that of the surface emitting laser 100 of the first embodiment except that the second confinement portion C2 is formed by an insulating material (for example, SiO₂, SIN, AlN, and the like) embedded in the recess 103b1.

(Modification 2)

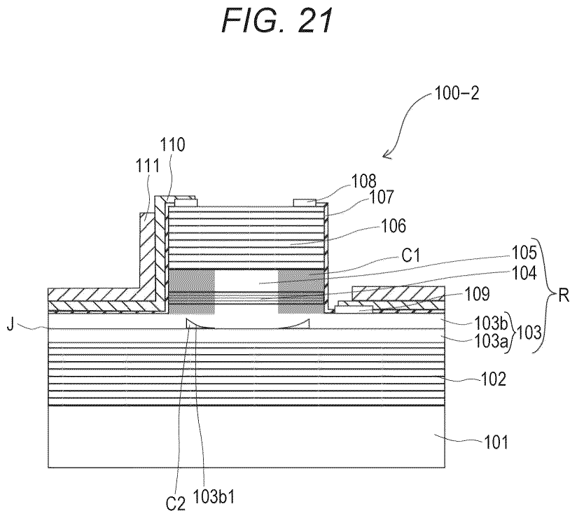

In a surface emitting laser 100-2 of Modification 2, as illustrated in FIG. 21, each of the recess 103b1 and the second confinement portion C2 may have a curved surface shape protruding toward the joint interface as a whole (a curved surface shape approaching the joint interface as approaching the center). That is, the cross section of the recess 103b1 may have a shape (for example, a curved surface shape) that becomes shallower as approaching the part of the central portion of the resonator R in the thickness direction (for example, the lower portion of the central portion of the second constituent layer 103b of the first cladding layer 103) surrounded by the recess 103b1. Thus, even when the inner diameter of the recess 103b1 is small, light scattering loss can be suppressed, the mode shape can be improved, and deterioration of characteristics can be suppressed.

(Modification 3)

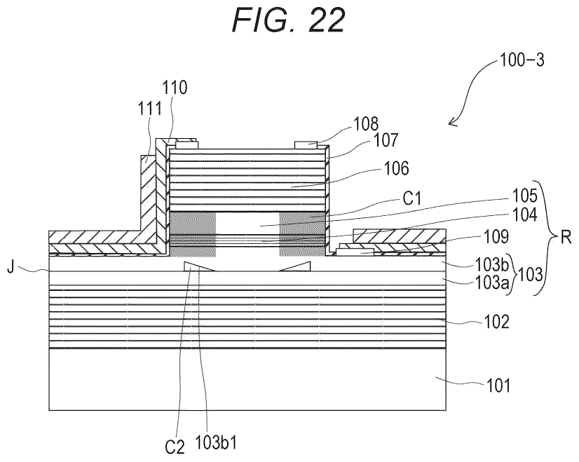

In a surface emitting laser 100-3 of Modification 3, as illustrated in FIG. 22, each of the recess 103b1 and the second confinement portion C2 may have a tapered shape approaching the joint interface as a whole as approaching the center. That is, the cross section of the recess 103b1 may have a shape (for example, a tapered shape) that becomes shallower as approaching the part of the central portion of the resonator R in the thickness direction (for example, the lower portion of the central portion of the second constituent layer 103b of the first cladding layer 103) surrounded by the recess 103b1. Thus, even when the inner diameter of the recess 103b1 is small, light scattering loss can be suppressed, the mode shape can be improved, and deterioration of characteristics can be suppressed.

(Modification 4)

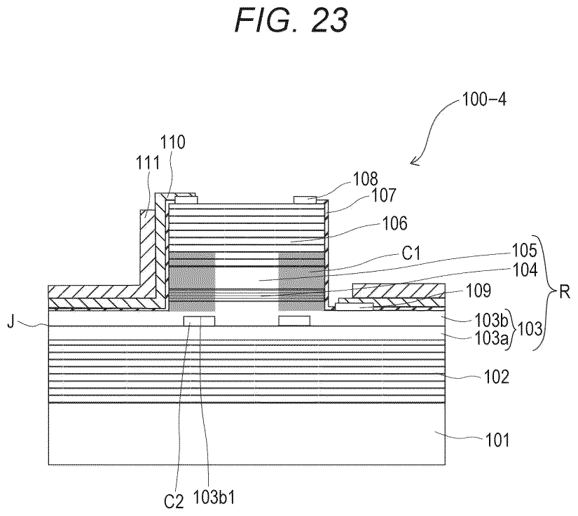

As illustrated in FIG. 23, a surface emitting laser 100-4 of Modification 4 has a configuration similar to that of the surface emitting laser 100 of the first embodiment except that the first confinement portion C1 also surrounds the lower portion of the central portion of the second multilayer film reflector 106. The surface emitting laser 100-4 can be manufactured by a manufacturing method similar to the method for manufacturing the surface emitting laser 100.

With the surface emitting laser 100-4, it is necessary to perform the ion implantation, the hole diffusion, the impurity diffusion, or the like more deeply at the time of generating the first confinement portion C1, but since the first confinement portion C1 is extended to the anode electrode 108 side, current confinement to the active layer 104 can be performed earlier, and furthermore, current injection efficiency to the active layer 104 can be further enhanced.

(Modification 5)

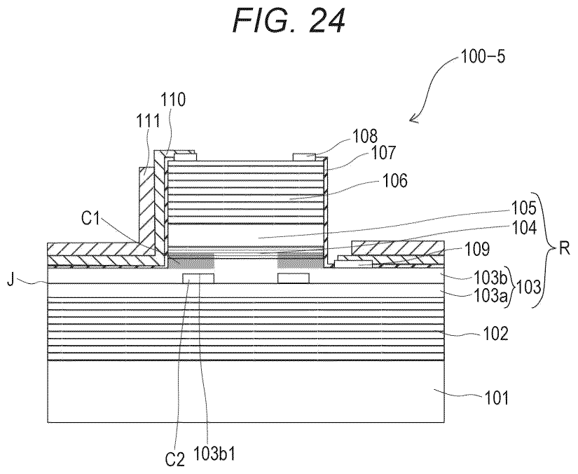

As illustrated in FIG. 24, a surface emitting laser 100-5 of Modification 5 has a configuration similar to that of the surface emitting laser 100 of the first embodiment except that the first confinement portion C1 surrounds only the lower portion of the central portion of the active layer 104 and the upper portion of the central portion of the first cladding layer 103. The surface emitting laser 100-5 can be manufactured by a manufacturing method similar to the method for manufacturing the surface emitting laser 100 except that the depth of the ion implantation, the impurity diffusion, the hole diffusion, or the like into the second constituent layer 103b of the first cladding layer 103 is shallow.

With the surface emitting laser 100-5, although the current confinement effect in the active layer 104 is inferior as compared to that of the surface emitting laser 100, for example, the ion implantation, the hole diffusion, the impurity diffusion, or the like is only required to be performed very shallowly when the first confinement portion C1 is generated, so that the width controllability is more excellent and the yield can be further improved.

(Modification 6)

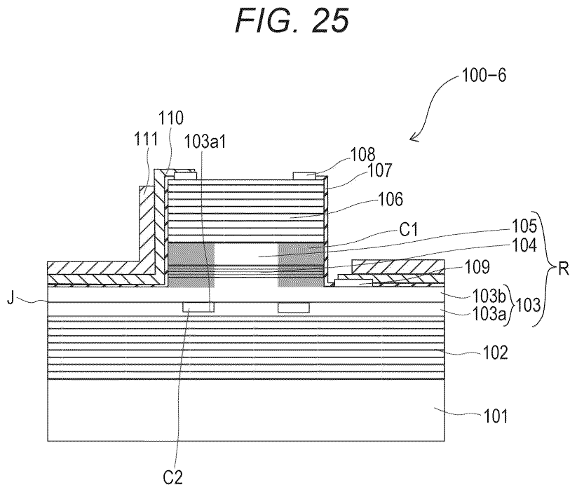

As illustrated in FIG. 25, a surface emitting laser 100-6 of Modification 6 has a configuration similar to that of the surface emitting laser 100 of the first embodiment except that the second confinement portion C2 is provided on the joint surface of the first constituent layer 103a of the first cladding layer 103 with the second constituent layer 103b.

That is, in the surface emitting laser 100-6, the second confinement portion C2 is provided on the first joint surface, which is the joint surface of the first constituent portion with the second constituent portion, of the first constituent portion on one side (for example, the lower side) and the second constituent portion on the other side (for example, the upper side) of the joint portion J. Here, the first constituent portion includes at least the first constituent layer 103a among the substrate 101, the first multilayer film reflector 102, and the first constituent layer 103a of the first cladding layer 103. The second constituent portion includes at least the second constituent layer 103b among the second constituent layer 103b of the first cladding layer 103, the active layer 104, the second cladding layer 105, and the second multilayer film reflector 106.

The surface emitting laser 100-6 can be manufactured by a manufacturing method similar to the method for manufacturing the surface emitting laser 100 except that the frame-shaped recess 103a1 is formed in the first constituent layer 103a.

(Modification 7)

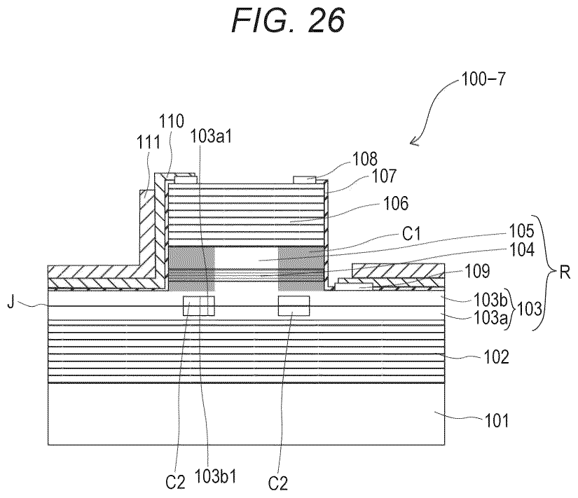

As illustrated in FIG. 26, a surface emitting laser 100-7 of Modification 7 has a configuration similar to that of the surface emitting laser 100 of the first embodiment except that the second confinement portion C2 is also provided on the joint surface of the first constituent layer 103a of the first cladding layer 103 with the second constituent layer 103b.

That is, in the surface emitting laser 100-7, the second confinement portion C2 is provided on the first joint surface, which is the joint surface of the first constituent portion with the second constituent portion, and the second joint surface, which is the joint surface with the first constituent portion of the second constituent portion, of the first constituent portion on one side (for example, the lower side) and the second constituent portion on the other side (for example, the upper side) of the joint portion J. Here, the first constituent portion includes at least the first constituent layer 103a among the substrate 101, the first multilayer film reflector 102, and the first constituent layer 103a of the first cladding layer 103. The second constituent portion includes at least the second constituent layer 103b among the second constituent layer 103b of the first cladding layer 103, the active layer 104, the second cladding layer 105, and the second multilayer film reflector 106.

The surface emitting laser 100-7 can be manufactured by a manufacturing method similar to the method for manufacturing the surface emitting laser 100 except that the recess 103a1 is formed in the first constituent layer 103a.

With the surface emitting laser 100-6, since the thickness of the second confinement portion C2 is substantially increased, it is possible to obtain a more light confinement effect in the active layer 104.

(Modification 8)

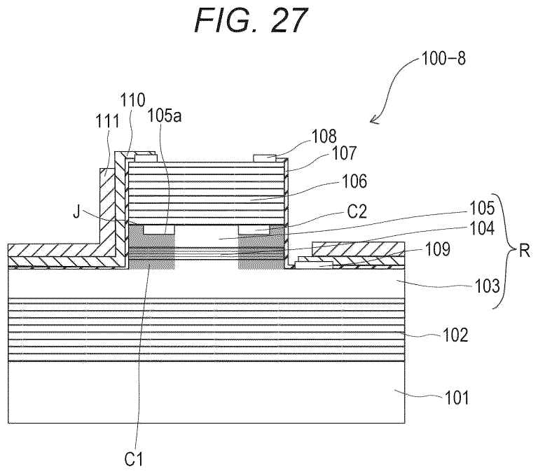

As illustrated in FIG. 27, a surface emitting laser 100-8 of Modification 8 has a configuration similar to that of the surface emitting laser 100 except that the joint portion J exists between the second multilayer film reflector 106 and the resonator R (for example, the second cladding layer 105), and the second confinement portion C2 is provided on the joint surface of the second cladding layer 105 with the second multilayer film reflector 106.

That is, in the surface emitting laser 100-8, the second confinement portion C2 is provided on the first joint surface, which is the joint surface of the first constituent portion with the second constituent portion, of the first constituent portion on one side (for example, the lower side) and the second constituent portion on the other side (for example, the upper side) of the joint portion J. Here, the first constituent portion includes at least the second cladding layer 105 among of the substrate 101, the first multilayer film reflector 102, the first cladding layer 103, the active layer 104, and the second cladding layer 105. The second constituent portion includes the second multilayer film reflector 106.

An example of a method of manufacturing the surface emitting laser 100-8 will be briefly described.

Process 1: The first multilayer film reflector 102, the first cladding layer 103, the active layer 104, and the second cladding layer 105 are stacked in this order on the substrate 101 (first substrate 101) to generate the first stacked body.

Process 2: A frame-shaped recess 105a is formed by etching the second cladding layer 105 of the first stacked body, and the semi-insulating material or the insulating material is embedded in the recess 105a as necessary, thereby generating the second confinement portion C2.

Process 3: The ion implantation, the hole diffusion, the impurity diffusion, or the like is performed on the second cladding layer 105 of the first stacked body to form the frame-shaped current confinement portion, thereby generating the first confinement portion C1. The depth of the ion implantation, the hole diffusion, the impurity diffusion, or the like at this time is, for example, up to the upper portion of the first cladding layer 103.

Process 4: The second multilayer film reflector 106 is stacked on the second substrate 112 to generate a second stacked body.

Process 5: The second cladding layer 105 of the first stacked body and the second multilayer film reflector 106 of the second stacked body are joined by, for example, any one of the joining methods (1) to (4) described above.

Thereafter, processes similar to processes S4 to S11 in FIG. 3 are performed.

With the surface emitting laser 100-8, since the second confinement portion C2 is provided on the anode electrode 108 side (upstream side of the current passage) with respect to the active layer 104, for example, the current confinement in the active layer 104 by the second confinement portion C2 can be more effectively performed. Moreover, with the surface emitting laser 100-8, since the current path in the first cladding layer 103 can be secured by adjusting the depth of the ion implantation, the hole diffusion, the impurity diffusion, or the like with respect to the second cladding layer 105 at the time of manufacturing, the second cladding layer 105 does not need to be grown twice, and the first cladding layer 103 does not need to be grown twice.

(Modification 9)

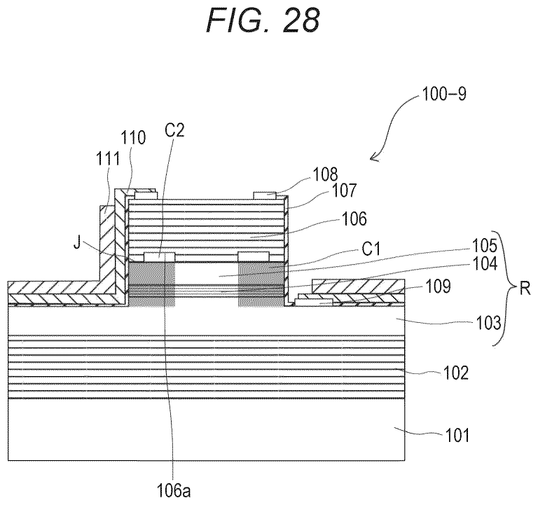

As illustrated in FIG. 28, a surface emitting laser 100-9 of Modification 9 has a configuration similar to that of the surface emitting laser 100-8 of Modification 8 except that the second confinement portion C2 is provided on the joint surface with the resonator R of the second multilayer film reflector 106.

That is, in the surface emitting laser 100-9, the second confinement portion C2 is provided on the second joint surface, which is the joint surface of the second constituent portion with the first constituent portion, of the first constituent portion on one side (for example, the lower side) and the second constituent portion on the other side (for example, the upper side) of the joint portion J. Here, the first constituent portion includes at least the second cladding layer 105 among of the substrate 101, the first multilayer film reflector 102, the first cladding layer 103, the active layer 104, and the second cladding layer 105. The second constituent portion includes the second multilayer film reflector 106.

An example of a method of manufacturing the surface emitting laser 100-9 will be briefly described.

Process 1: The first multilayer film reflector 102, the first cladding layer 103, the active layer 104, and the second cladding layer 105 are stacked in this order on the substrate 101 (first substrate 101) to generate the first stacked body.

Process 2: The ion implantation, the hole diffusion, the impurity diffusion, or the like is performed on the second cladding layer 105 of the first stacked body to form the frame-shaped current confinement portion, thereby generating the first confinement portion C1. The depth of the ion implantation, the hole diffusion, the impurity diffusion, or the like at this time is, for example, up to the upper portion of the first cladding layer 103.

Process 3: The second multilayer film reflector 106 is stacked on the second substrate 112 to generate a second stacked body. Process 4: A frame-shaped recess 106a is formed by etching the second multilayer film reflector 106 of the second stacked body, and the semi-insulating material or the insulating material is embedded in the recess 106a as necessary, thereby generating the second confinement portion C2.

Process 5: The second cladding layer 105 of the first stacked body and the second multilayer film reflector 106 of the second stacked body are joined by, for example, any one of the joining methods (1) to (4) described above.

Thereafter, processes similar to processes S4 to S11 in FIG. 3 are performed.

With the surface emitting laser 100-9, an effect similar to that of the surface emitting laser 100-8 of Modification 8 can be obtained, and since the second confinement portion C2 is arranged on the more upstream side of the current passage, the current confinement effect can be obtained from an earlier stage, and the current injection efficiency into the active layer 104 can be improved.

(Modification 10)

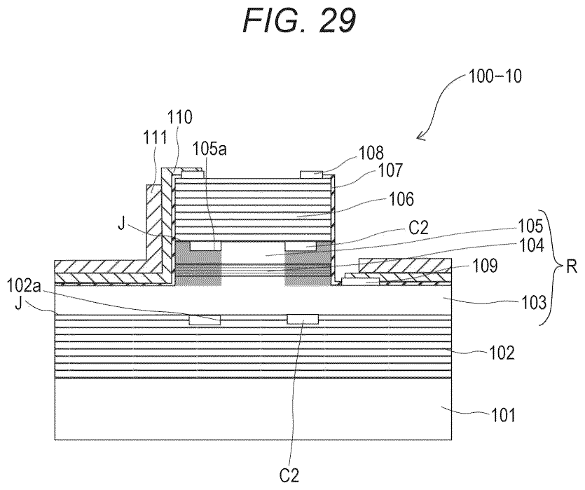

As illustrated in FIG. 29, a surface emitting laser 100-10 of Modification 10 has a configuration similar to that of the surface emitting laser 100 of the first embodiment except that the joint portion J exists between the second multilayer film reflector 106 and the resonator R (for example, the second cladding layer 105), and the joint portion J exists between the first multilayer film reflector 102 and the resonator R (for example, the first cladding layer 103), and the second confinement portion C2 is provided on the joint surface of the second cladding layer 105 with the second multilayer film reflector 106, and the second confinement portion C2 is provided on the joint surface of the first multilayer film reflector 102 with the first cladding layer 103.

That is, in the surface emitting laser 100-10, the one (lower) second confinement portion C2 is provided on the first joint surface, which is the joint surface of the first constituent portion with the second constituent portion, of the first constituent portion on one side (for example, the lower side) and the second constituent portion on the other side (for example, the upper side) of the one (lower) joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

In the surface emitting laser 100-10, the other (upper) second confinement portion C2 is provided on the first joint surface, which is the joint surface of the first constituent portion with the second constituent portion, of the first constituent portion on one side (for example, the lower side) and the second constituent portion on the other side (for example, the upper side) of the other (upper) joint portion J. Here, the first constituent portion includes at least the second cladding layer 105 among of the substrate 101, the first multilayer film reflector 102, the first cladding layer 103, the active layer 104, and the second cladding layer 105. The second constituent portion includes the second multilayer film reflector 106.

An example of a method of manufacturing the surface emitting laser 100-10 will be briefly described.

Process 1: The first multilayer film reflector 102 is stacked on the substrate 101 (first substrate 101) to generate the first stacked body.

Process 2: A frame-shaped recess 102a is formed by etching the first multilayer film reflector 102 of the first stacked body, and the semi-insulating material or the insulating material is embedded in the recess 102a as necessary, thereby generating the second confinement portion C2.

Process 3: The second multilayer film reflector 106 is stacked on the second substrate 112 to generate a second stacked body.

Process 4: The first cladding layer 103, the active layer 104, and the second cladding layer 105 are stacked in this order from the third substrate side on the third substrate to generate a third stacked body.

Process 5: A frame-shaped recess 105a is formed by etching the second cladding layer 105 of the third stacked body, and the semi-insulating material or the insulating material is embedded in the recess 105a as necessary, thereby generating the second confinement portion C2.

Process 6: The ion implantation, the hole diffusion, the impurity diffusion, or the like is performed on the second cladding layer 105 of the third stacked body to form the frame-shaped current confinement portion, thereby generating the first confinement portion C1. The implantation depth and the diffusion depth at this time are, for example, up to the upper portion of the first cladding layer 103.

Process 7: The second multilayer film reflector 106 of the second stacked body and the second cladding layer 105 of the third stacked body are joined by, for example, any one of the joining methods (1) to (4) described above, and the third substrate of the third stacked body is removed by thinning and wet etching. As a result, the first cladding layer 103 of the third stacked body is exposed.

Process 8: The first cladding layer 103 of the third stacked body and the first multilayer film reflector 102 of the first stacked body are joined by, for example, any one of the joining methods (1) to (4) described above.

Thereafter, processes similar to processes S4 to S11 in FIG. 3 are performed.

With the surface emitting laser 100-10, an effect similar to that of the surface emitting laser 100-8 of Modification 8 can be obtained, and since the second confinement portion C2 is also provided in the first multilayer film reflector 102, the light confinement effect in the active layer 104 can be further obtained.

(Modification 11)

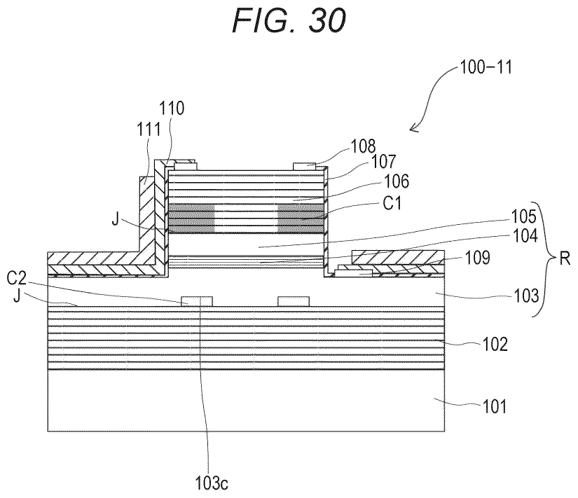

As illustrated in FIG. 30, a surface emitting laser 100-11 of Modification 11 has a configuration similar to that of the surface emitting laser 100 of the first embodiment except that the joint portion J exists between the second multilayer film reflector 106 and the resonator R (second cladding layer 105), and the joint portion J exists between the first multilayer film reflector 102 and the first cladding layer 103, and the first confinement portion C1 is provided in the second multilayer film reflector 106, and the second confinement portion C2 is provided on the joint surface of the first cladding layer 103 with the first multilayer film reflector 102.

That is, in the surface emitting laser 100-11, the second confinement portion C2 is provided on the second joint surface, which is the joint surface of the second constituent portion with the first constituent portion, of the first constituent portion on one side (for example, the lower side) and the second constituent portion on the other side (for example, the upper side) of the (lower) joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

In the surface emitting laser 100-11, the first confinement portion C1 is provided in a region including the second joint surface, which is the joint surface of the second constituent portion with the first constituent portion, of the second constituent portion of the first constituent portion on one side (for example, the lower side) and the second constituent portion on the other side (for example, the upper side) of the other (upper) joint portion J. Here, the first constituent portion includes at least the second cladding layer 105 among the substrate 101, the first multilayer film reflector 102, the first cladding layer 103, the active layer 103, and the second cladding layer 105. The second constituent portion includes the second multilayer film reflector 106.

An example of a method of manufacturing the surface emitting laser 100-11 will be briefly described.

Process 1: The first multilayer film reflector 102 is stacked on the substrate 101 (first substrate 101) to generate the first stacked body.

Process 2: The second multilayer film reflector 106 is stacked on the second substrate 112 to generate a second stacked body.

Process 3: The ion implantation, the hole diffusion, the impurity diffusion, or the like is performed on the second multilayer film reflector 106 of the second stacked body to form the frame-shaped current confinement portion, thereby generating the first confinement portion C1.

Process 4: The second cladding layer 105, the active layer 104, and the first cladding layer 103 are stacked in this order from the third substrate side on the third substrate to generate the third stacked body.

Process 5: A frame-shaped recess 103c is formed by etching the first cladding layer 103 of the third stacked body, and the semi-insulating material or the insulating material is embedded in the recess 103c as necessary, thereby generating the second confinement portion C2.

Process 6: The first multilayer film reflector 102 of the first stacked body and the first cladding layer 103 of the third stacked body are joined by, for example, any one of the joining methods (1) to (4) described above, and the third substrate of the third stacked body is removed by thinning and wet etching. As a result, the second cladding layer 105 of the third stacked body is exposed.

Process 7: The second cladding layer 105 of the third stacked body and the second multilayer film reflector 106 of the second stacked body are joined by, for example, any one of the joining methods (1) to (4) described above.

Thereafter, processes similar to processes S4 to S11 in FIG. 3 are performed.

With the surface emitting laser 11, an effect similar to that of the surface emitting laser 100 of the first embodiment can be obtained, and since the first confinement portion C1 is provided in the second multilayer film reflector 106 (on the more upstream side of the current passage), the current confinement effect in the active layer 104 can be obtained earlier.

(Modification 12)

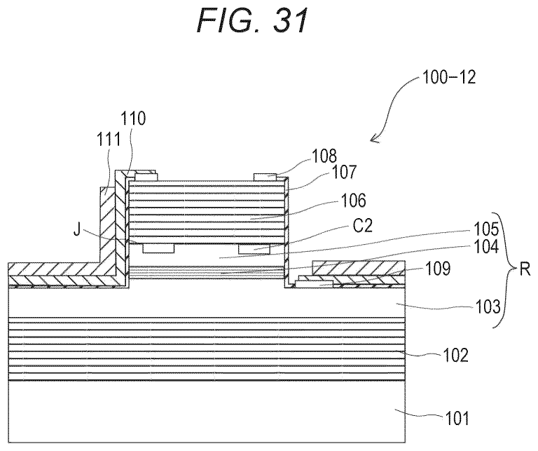

As illustrated in FIG. 31, a surface emitting laser 100-12 of Modification 12 has a configuration similar to that of the surface emitting laser 100-8 of Modification 8 except that the first confinement portion C1 is not provided. The surface emitting laser 100-12 can be manufactured by a manufacturing method similar to the method for manufacturing the surface emitting laser 100-8 except that the frame-shaped high electric resistance layer (first confinement portion C1) is not formed on the second cladding layer 105 of the first stacked body.

That is, in the surface emitting laser 100-12, the second confinement portion C2 is provided on the first joint surface, which is the joint surface of the first constituent portion with the second constituent portion, of the first constituent portion on one side (for example, the lower side) and the second constituent portion on the other side (for example, the upper side) of the joint portion J. Here, the first constituent portion includes at least the second cladding layer 105 among of the substrate 101, the first multilayer film reflector 102, the first cladding layer 103, the active layer 104, and the second cladding layer 105. The second constituent portion includes the second multilayer film reflector 106.

With the surface emitting laser 12, for example, by providing the second confinement portion C2 with a current confinement function in addition to the light confinement function, it is possible to obtain the current confinement effect in addition to the light confinement effect in the active layer 104 even without the first confinement portion C1. Furthermore, with the surface emitting laser 100-12, since the first confinement portion C1 is not provided, the number of manufacturing steps can be reduced, and productivity can be improved.

(Modification 13)

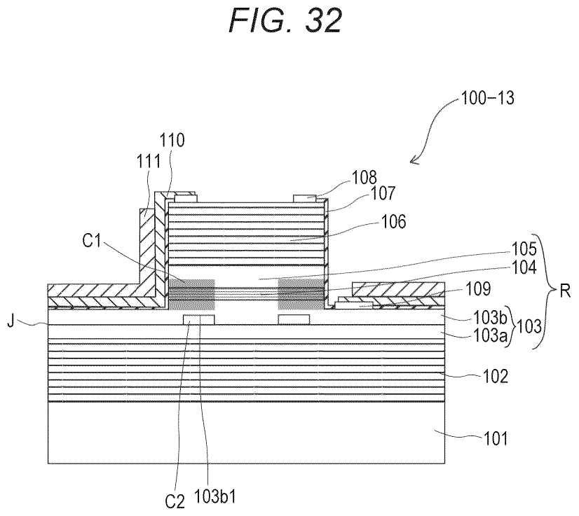

As illustrated in FIG. 32, a surface emitting laser 100-13 of Modification 13 has a configuration similar to that of the surface emitting laser 100 of the first embodiment except that the upper portion of the second cladding layer 105 is not surrounded by the first confinement portion C1. The surface emitting laser 100-13 can be manufactured by a manufacturing method similar to the method for manufacturing the surface emitting laser 100 except that the depth of the ion implantation, the hole diffusion, the impurity diffusion, or the like into the second constituent layer 103b of the first cladding layer 103 is shallow.

With the surface emitting laser 100-13, although the current confinement effect in the active layer 104 is inferior as compared to that of the surface emitting laser 100, for example, the ion implantation, the hole diffusion, the impurity diffusion, or the like is only required to be performed more shallowly when the first confinement portion C1 is generated, so that the width controllability is more excellent and the yield can be further improved.

(Modification 14)

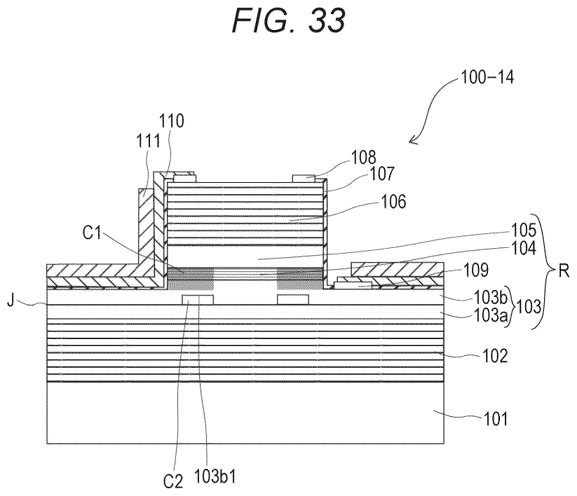

As illustrated in FIG. 33, a surface emitting laser 100-14 of Modification 14 has a configuration similar to that of the surface emitting laser 100 of the first embodiment except that the second cladding layer 105 is not surrounded by the first confinement portion C1. The surface emitting laser 100-14 can be manufactured by a manufacturing method similar to the method for manufacturing the surface emitting laser 100 of Modification 13 except that the depth of the ion implantation, the hole diffusion, or the impurity diffusion into the second constituent layer 103b of the first cladding layer 103 is shallow.

With the surface emitting laser 100-14, although the current confinement effect in the active layer 104 is inferior as compared to that of the surface emitting laser 100, for example, the ion implantation, the hole diffusion, the impurity diffusion, or the like is only required to be performed more shallowly when the first confinement portion C1 is generated, so that the width controllability is more excellent and the yield can be further improved.

(Modification 15)

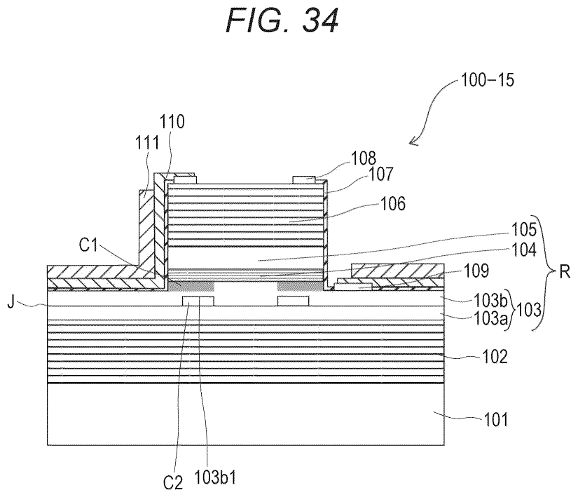

As illustrated in FIG. 34, a surface emitting laser 100-15 of Modification 15 has a configuration similar to that of the surface emitting laser 100 of the first embodiment except that the second cladding layer 105 and the active layer 104 are not surrounded by the first confinement portion C1. The surface emitting laser 100-15 can be manufactured by a manufacturing method similar to the method for manufacturing the surface emitting laser 100-14 of Modification 14 except that the depth of the ion implantation, the hole diffusion, the impurity diffusion, or the like into the second constituent layer 103b of the first cladding layer 103 is shallow.

With the surface emitting laser 100-15, although the current confinement effect in the active layer 104 is inferior as compared to that of the surface emitting laser 100, for example, the ion implantation, the hole diffusion, the impurity diffusion, or the like is only required to be performed much more shallowly when the first confinement portion C1 is generated, so that the width controllability is much more excellent, and the yield can be remarkably improved.

### 4. Surface Emitting Laser According to Second Embodiment of Present Technology

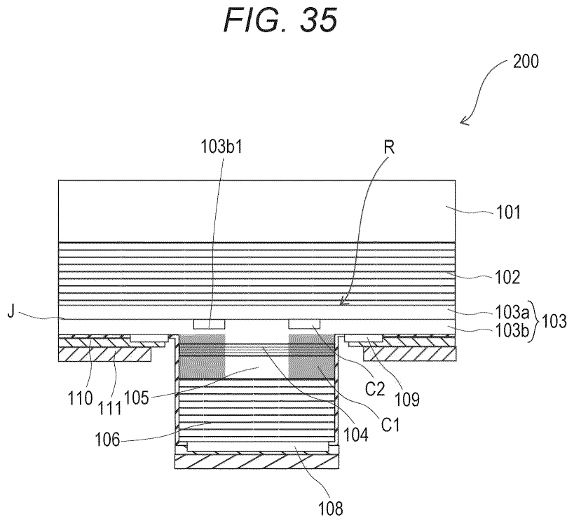

Hereinafter, a surface emitting laser 200 according to a second embodiment of the present technology will be described. As illustrated in FIG. 35, the surface emitting laser 200 of the second embodiment has substantially a configuration similar to that of the surface emitting laser 100 of the first embodiment except that it is a back surface emission type. That is, in the surface emitting laser 200, the reflectance of the second multilayer film reflector 106 is set slightly higher than the reflectance of the first multilayer film reflector 102, and a substrate transparent to at least an oscillation wavelength is used as the substrate 101. Moreover, in the surface emitting laser 200, as an example, the first multilayer film reflector 102 is n-type, and the second multilayer film reflector 106 is p-type.

In the surface emitting laser 200, the cathode electrode 109 is provided around the mesa, and the anode electrode 108 having a flat plate shape is provided at the top of the mesa.

In the surface emitting laser 200, for example, the current supplied from the laser driver and flowing in from the anode electrode 108 passes through the second cladding layer 105, is injected into the active layer 104 while being confined in the first confinement portion C1, and the active layer 104 emits light. The light generated in the active layer 104 reciprocates between the first and second multilayer film reflectors 102 and 106, is confined in the second confinement portion C2 during the reciprocation, is amplified in the active layer 104, and is emitted from the back surface of the substrate 101 to the outside when the oscillation condition is satisfied. The current injected into the active layer 104 reaches the cathode electrode 109 via the second constituent layer 103b of the first cladding layer 103, and flows out from the cathode electrode 109 to, for example, the laser driver.

The surface emitting laser 200 has an effect similar to that of the surface emitting laser 100 of the first embodiment.

### 5. Surface Emitting Laser According to Third Embodiment of Present Technology

Hereinafter, a surface emitting laser 300 according to a third embodiment of the present technology will be described.

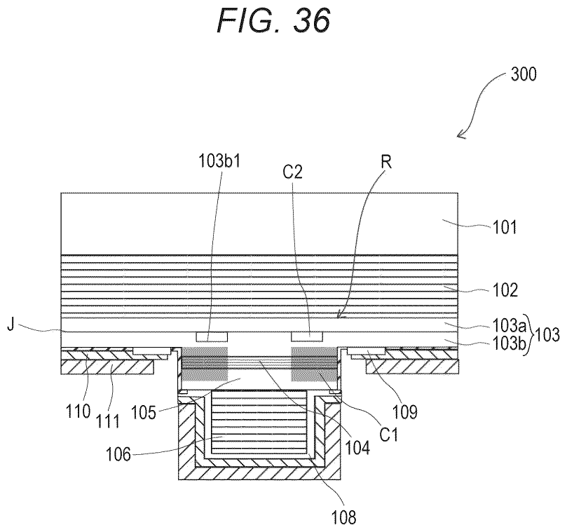

As illustrated in FIG. 36, the surface emitting laser 300 of the third embodiment has a configuration similar to that of the surface emitting laser 200 of the second embodiment except that it has a double intracavity structure. That is, in the surface emitting laser 300, the anode electrode 108 is provided along the mesa so as to be in contact with the second cladding layer 105 of the resonator, and the cathode electrode 109 is provided so as to be in contact with the first cladding layer 103 of the resonator.

The surface emitting laser 300 operates similarly to the surface emitting laser 200. The surface emitting laser 300 has an effect similar to that of the surface emitting laser 200.

### 6. Surface Emitting Laser According to Fourth Embodiment of Present Technology

(1) Configuration of Surface Emitting Laser

Hereinafter, a surface emitting laser 400 according to a fourth embodiment of the present technology will be described.

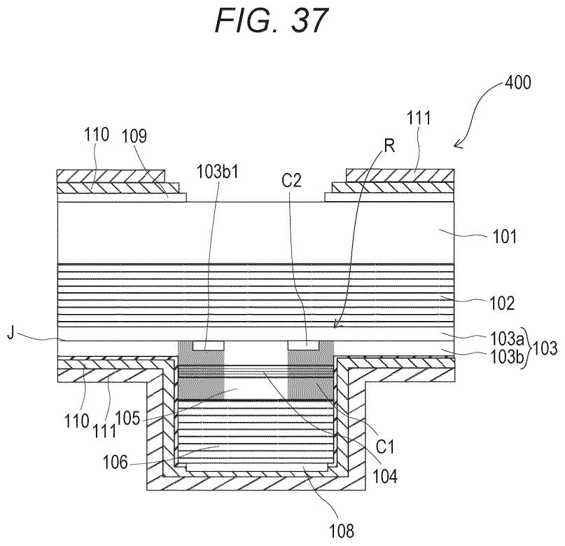

As illustrated in FIG. 37, the surface emitting laser 400 of the fourth embodiment has a configuration similar to that of the surface emitting laser 200 of the second embodiment except that it has a back electrode structure. More specifically, in the surface emitting laser 400, the cathode electrode 109 is provided on the back surface (the surface on the side opposite to the first multilayer film reflector 102 side) of the substrate 101 having conductivity, and the anode electrode 108 having a flat plate shape is provided on the top of the mesa (for example, the surface on the side opposite to the second cladding layer 105 side of the second multilayer film reflector 106).

In the surface emitting laser 400, the first confinement portion C1 is provided in a region including the second joint surface, which is the joint surface of the second constituent portion with the first constituent portion, of the second constituent portion of the first constituent portion on one side (for example, the upper side) and the second constituent portion on the other side (for example, the lower side) of the joint portion J. Here, the first constituent portion includes at least the first constituent layer 103a among the substrate 101, the first multilayer film reflector 102, and the first constituent layer 103a of the first cladding layer 103. The second constituent portion includes at least the second constituent layer 103b among the second constituent layer 103b of the first cladding layer 103, the active layer 104, the second cladding layer 105, and the second multilayer film reflector 106.

More specifically, in the surface emitting laser 400, the first confinement portion C1 surrounds the entire region in the thickness direction of the central portion of the second constituent layer 103b of the first cladding layer 103, the entire region in the thickness direction of the central portion of the active layer 104, and the entire region in the thickness direction of the second cladding layer 105. In the surface emitting laser 400, since the cathode electrode 109 is provided on the back surface of the substrate 101 and the anode electrode 108 is provided at the top of the mesa, a current path running on the second constituent layer 103b of the first cladding layer 103 in the lateral direction (in-plane direction) is unnecessary in the current passage. Therefore, there is no problem even if the first confinement portion C1 surrounds the entire region in the thickness direction of the second constituent layer 103b.

(2) Operation of Surface Emitting Laser

In the surface emitting laser 400, for example, the current supplied from the laser driver and flowing in from the anode electrode 108 passes through the second multilayer film reflector 106, is then confined (narrowed) by the first and second confinement portions C1 and C2, and is injected into the active layer 104. At this time, the active layer 104 emits light, and the light generated in the active layer 104 reciprocates between the first and second multilayer film reflectors 102 and 106, is confined in the second confinement portion C2 during the reciprocation, is amplified in the active layer 104, and is emitted from the back surface of the substrate 101 to the outside when the oscillation condition is satisfied. The current that has passed through the active layer 104 flows into the cathode electrode 109 via the first cladding layer 103, the first multilayer film reflector 102, and the substrate 101, and flows out from the cathode electrode 109 to, for example, the laser driver.

(3) Method for Manufacturing Surface Emitting Laser

Hereinafter, a method for manufacturing the surface emitting laser 400 will be described with reference to the flowchart of FIG. 3. As an example, the surface emitting laser 400 is manufactured by a semiconductor manufacturing method using a semiconductor manufacturing apparatus.

<Step S1>

In step S1, the first stacked body generation processing is performed. In the first stacked body generation processing, as an example, the first multilayer film reflector 102 and the first constituent layer 103a of the first cladding layer 103 are stacked (for example, epitaxially grown at a growth temperature of 605° C.) on the substrate 101 (hereinafter also referred to as the “first substrate 101”) in the growth chamber by the chemical vapor deposition (CVD) method, for example, the metal organic chemical vapor deposition (MOCVD) method to generate the first stacked body L1 (see FIG. 4).

Note that, when the MOCVD is performed, for example, trimethylgallium ((CH₃)₃Ga) is used as a source gas of gallium, for example, trimethylaluminum ((CH₃)₃Al) is used as a source gas of aluminum, for example, trimethylindium ((CH₃)₃In) is used as a source gas of indium, and for example, trimethylarsenic (((CH₃)₃As) is used as a source gas of As. Furthermore, as a source gas of silicon, for example, monosilane (SiH₄) is used.

For example, carbon tetrabromide (CBr₄) is used as the carbon source gas.

<Step S2>

In step S2, the second stacked body generation processing is performed.

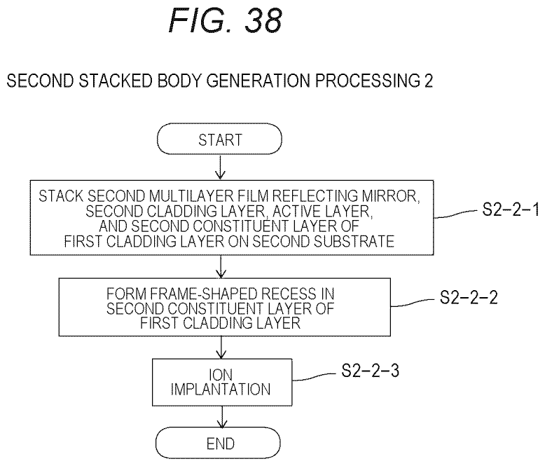

Hereinafter, a second stacked body generation processing 2 as an example of the second stacked body generation processing performed to manufacture the surface emitting laser 400 will be described with reference to a flowchart of FIG. 38.

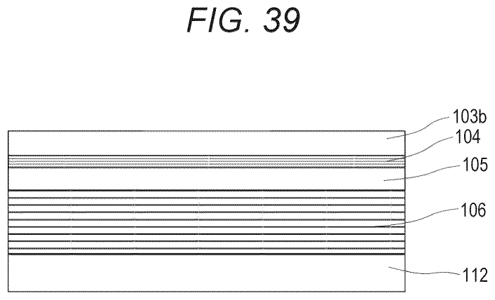

In step S2-2-1, as an example, the second multilayer film reflector 106, the second cladding layer 105, the active layer 104, and the second constituent layer 103b of the first cladding layer 103 are stacked (for example, epitaxially grown at a growth temperature of 605° C.) on the second substrate 112 in the growth chamber by the chemical vapor deposition (CVD) method, for example, the metal organic chemical vapor deposition (MOCVD) method described above to generate a stacked body (see FIG. 39).

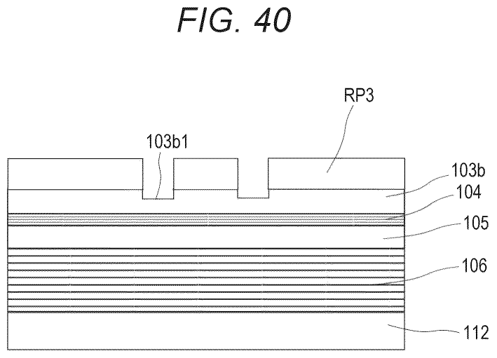

In step S2-2-2, the frame-shaped recess 103b1 (circular-shaped recess) is formed in the second constituent layer 103b of the first cladding layer 103 of the stacked body of FIG. 39 (see FIG. 40). Specifically, a resist pattern RP3 having a frame-shaped opening for forming the recess 103b1 is formed on second constituent layer 103b. Next, at least a part of the second constituent layer 103b is removed by etching by, for example, a wet etching method to form the recess 103b1. Thereafter, the resist pattern RP3 is removed. At this time, the inside of the recess 103b1 is an air layer. Thereafter, the above-described semi-insulating material or insulating material is embedded in the recess 103b1 as necessary. By executing step S2-2-2, the second confinement portion C2 is formed.

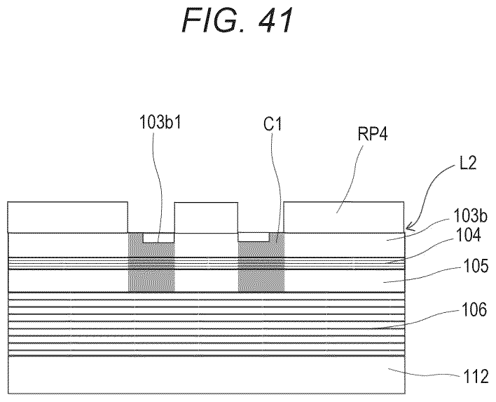

In step S2-2-3, ion implantation is performed (see FIG. 41). Specifically, a resist pattern RP4 opened only at a portion where the first confinement portion C1 is to be formed is formed on the second constituent layer 103b of the second cladding layer 103, and the ion implantation is performed. The ion-implanted region (region where ions exist) formed by this ion implantation extends, for example, across at least the entire region in the thickness direction of the second constituent layer 103b of the first cladding layer 103, the entire region in the thickness direction of the active layer 104, and the entire region in the thickness direction of the second cladding layer 105. Thereafter, the resist pattern RP4 is removed. At this time, the inside of the recess 103b1 is an air layer. Thereafter, the semi-insulating material or the insulating material is embedded in the recess 103b1 as necessary. As a result, the first confinement portion C1 is formed, and the second stacked body L2 is obtained.

Note that the order of steps S2-2-2 and S2-2-3 may be reversed. That is, after the ion implantation is performed on the second constituent layer 103b to generate the first confinement portion C1, the second confinement portion C2 may be generated by forming the frame-shaped recess 103b1.

<Step S3>

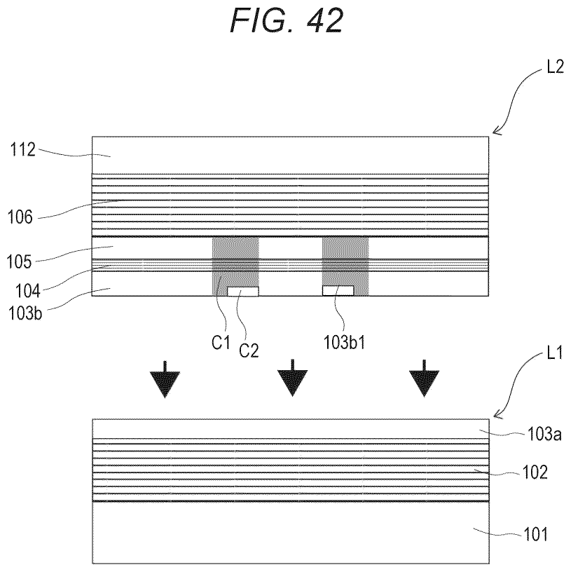

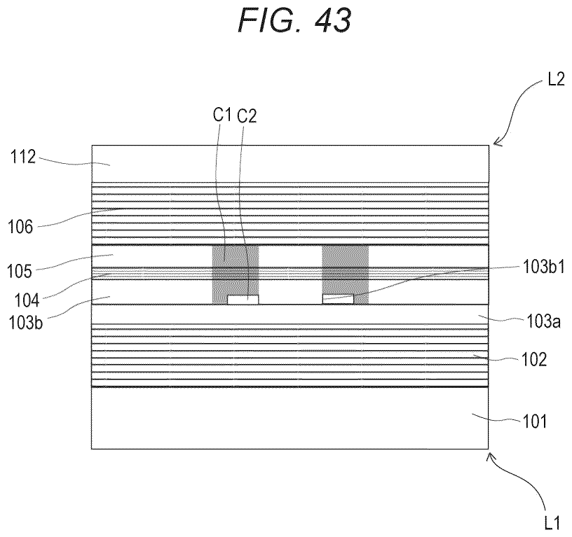

In step S3, the first and second stacked bodies are joined (see FIGS. 42 and 43). Specifically, for example, the first constituent layer 103a of the first cladding layer 103 of the first stacked body L1 and the second constituent layer 103b of the first cladding layer 103 of the second stacked body L2 are joined using any one of the above-described joining methods (1) to (4).

<Step S4>

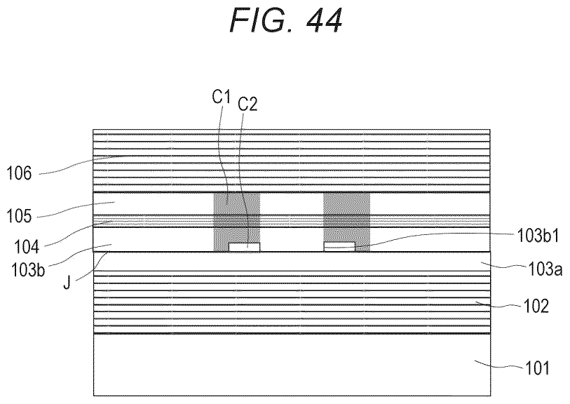

In step S4, the second substrate 112 is removed (see FIG. 44). Specifically, after the second substrate 112 (see FIG. 43) is ground to be thinned, the thinned second substrate 112 is removed by wet etching. As a result, the surface of the second multilayer film reflector 106 is exposed.

<Step S5>

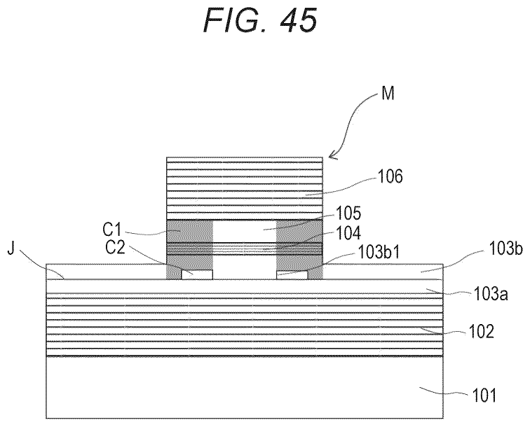

In step S5, the mesa M is formed (see FIG. 45). Specifically, as an example, upper portions of the second multilayer film reflector 106, the second cladding layer 105, the active layer 104, and the second constituent layer 103b of the first cladding layer 103 are etched to form the mesa M.

More specifically, a resist pattern for forming the mesa M is generated on the second multilayer film reflector 106 by photolithography. Next, using this resist pattern as a mask, the stacked body obtained by executing step S4 is etched until the second constituent layer 103b of the first cladding layer 103 is exposed (for example, until the side surface of the active layer 104 is completely exposed) by, for example, reactive ion etching (RIE etching) to form the mesa M having an outer diameter longer than the outer diameter of the recess 103b1 by 1 to 40 μm, for example. The etching here is performed until the etching bottom surface is located in the second constituent layer 103b of the first cladding layer 103. Thereafter, the resist pattern is removed.

<Step S6>

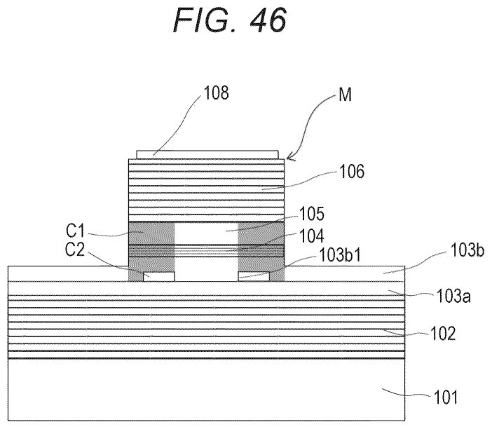

In step S6, the anode electrode 108 is formed (see FIG. 46). The anode electrode 108 can be formed by, for example, a lift-off method. In step S6, the anode electrode 108 is formed on the top of the mesa M (the surface of the second multilayer film reflector 106) by using, for example, a vacuum vapor deposition method, a sputtering method, or the like. More specifically, the anode electrode 108 is formed to have a diameter shorter than the diameter of the mesa M by, for example, 1 to 200 μm.

<Step S7>

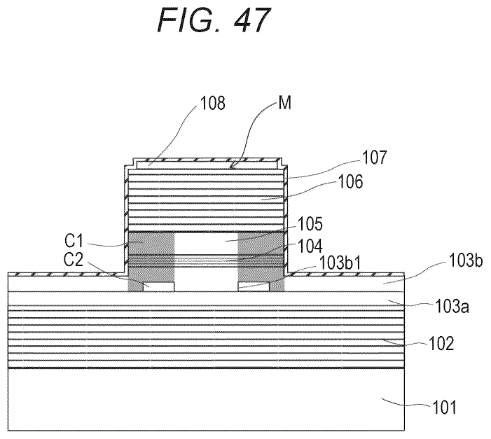

An insulating film 107 is formed (see FIG. 47). Specifically, the insulating film 107 is formed on the mesa M and its peripheral region by, for example, a vacuum vapor deposition method, a sputtering method, or the like.

<Step S8>

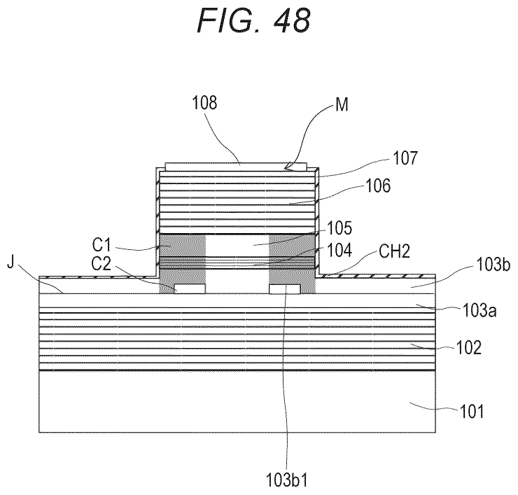

In step S8, a part of the insulating film 107 is removed (see FIG. 48). Specifically, the insulating film 107 on the anode electrode 108 is removed by, for example, an RIE method or a solution containing hydrogen fluoride. As a result, the anode electrode 108 is exposed.

<Step S9>

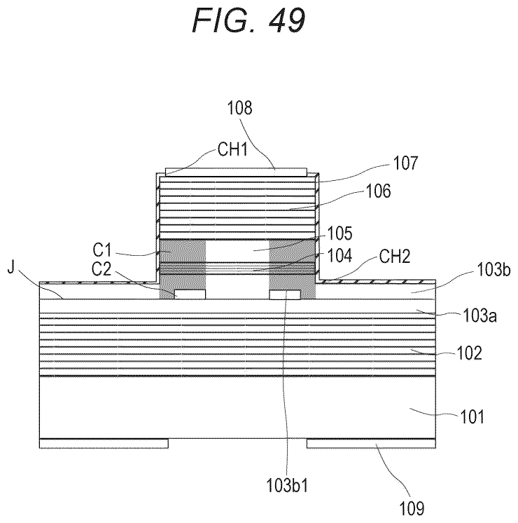

In step S9, the cathode electrode 109 is formed (see FIG. 49). Specifically, the frame-shaped (for example, annular) cathode electrode 109 is formed on the back surface of the substrate 101 by, for example, a lift-off method. At this time, the inner diameter side of the cathode electrode 109 serves as an emission port.

<Step S10>

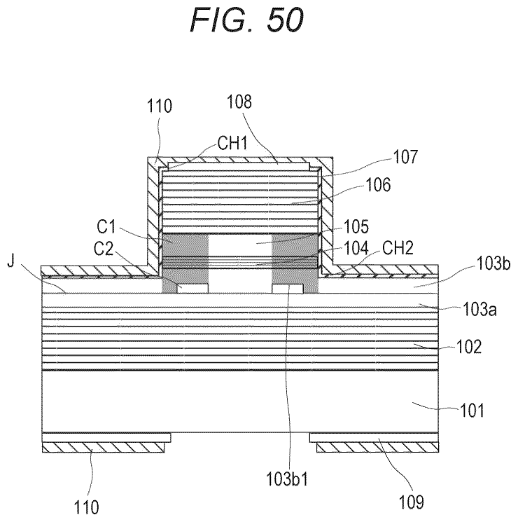

In step S10, the pad wiring 110 is formed (see FIG. 50). The pad wiring 110 can be formed by, for example, a lift-off method. The pad wiring 110 is formed on the mesa M and its peripheral region, and on the cathode electrode 109 by using, for example, a vacuum vapor deposition method, a sputtering method, or the like.

<Step S11>

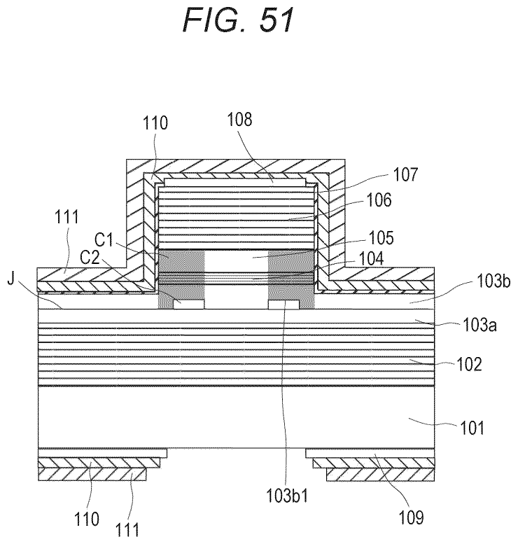

In step S11, plated wiring 111 is formed (see FIG. 51). The plated wiring 111 is formed on substantially the entire region of the pad wiring 110 formed on the mesa M and the peripheral region of the mesa M and the pad wiring 110 formed on the cathode electrode 109 by, for example, a plating method.

(4) Effects of Surface Emitting Laser and Method for Manufacturing the Same

The surface emitting laser 400 according to the fourth embodiment of the present technology has an effect similar to that of the surface emitting laser 100 of the first embodiment.

A method for manufacturing the surface emitting laser 400 includes a process of stacking a first structure including the first multilayer film reflector 102 and a first portion of a resonator (for example, the first constituent layer 103a of a first cladding layer 103) in this order on the first substrate 101 to generate the first stacked body L1, a process of generating the second stacked body L2, and a process of joining the first and second stacked bodies L1 and L2, in which in the process of generating the second stacked body L2, a second structure including the second multilayer film reflector 106 and a second portion of the resonator (for example, the second constituent layer 103b of the first cladding layer 103) are stacked in this order on the second substrate 112, the frame-shaped recess 103b1 is formed on the second portion of the resonator, and in the joining process, the second portion of the resonator in the second stacked body L2 and the first portion of the resonator in the first stacked body are joined.

According to the method for manufacturing the surface emitting laser 400, an effect similar to that of the surface emitting laser 100 of the first embodiment is obtained, and it is not necessary to grow the second constituent layer 103b of the first cladding layer 103 twice, and the number of manufacturing steps can be reduced.

7. Surface Emitting Lasers According to Modifications 1 to 4 of Fourth Embodiment of Present Technology

Hereinafter, surface emitting lasers according to Modifications 1 to 4 of the fourth embodiment of the present technology will be described.

(Modification 1)

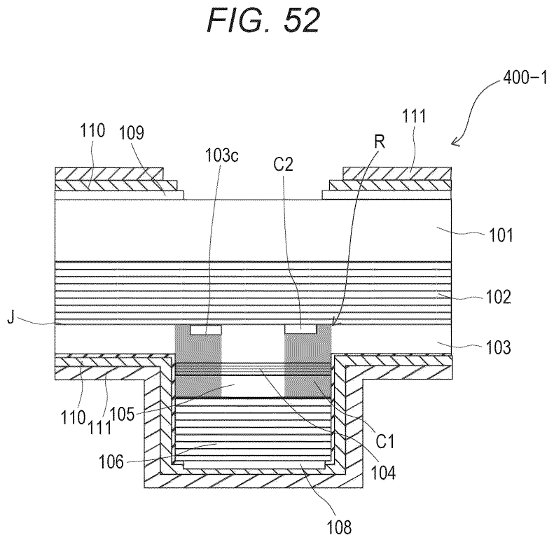

As illustrated in FIG. 52, in a surface emitting laser 400-1 of Modification 1, a joint portion J exists between the first multilayer film reflector 102 and the first cladding layer 103.

In the surface emitting laser 400-1, as an example, the entire region in the thickness direction of the central portion of the first cladding layer 103, the entire region in the thickness direction of the central portion of the active layer 104, and the entire region in the thickness direction of the central portion of the second cladding layer 105 are surrounded by the first confinement portion C1.

In the surface emitting laser 400-1, as an example, the frame-shaped recess 103c (second confinement portion C2) is formed on the joint surface of the first cladding layer 103 with the first multilayer film reflector 102.

That is, in the surface emitting laser 400-1, the first confinement portion C1 is provided in a region including the second joint surface, which is the joint surface of the second constituent portion with the first constituent portion, of the second constituent portion of the first constituent portion on one side (for example, the upper side) and the second constituent portion on the other side (for example, the lower side) of the joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

In the surface emitting laser 400-1, the second confinement portion C2 is provided on the second joint surface, which is the joint surface of the second constituent portion with the first constituent portion, of the first constituent portion on one side (for example, the upper side) and the second constituent portion on the other side (for example, the lower side) of the joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

An example of a method for manufacturing the surface emitting laser 400-1 will be briefly described.

Process 1: The first multilayer film reflector 102 is stacked on the substrate 101 (first substrate 101) to generate the first stacked body.

Process 2: The second multilayer film reflector 106, the second cladding layer 105, the active layer 104, and the first cladding layer 103 are stacked in this order from the second substrate 112 side on the second substrate 112 to generate a second stacked body.

Process 3: The frame-shaped recess 103c is formed by etching the first cladding layer 103 of the second stacked body, and the semi-insulating material or the insulating material is embedded in the recess 103c as necessary, thereby generating the second confinement portion C2.

Process 4: The ion implantation, the hole diffusion, the impurity diffusion, or the like is performed on the first cladding layer 103 of the second stacked body to form the frame-shaped current confinement portion, thereby generating the first confinement portion C1. The implantation depth and the diffusion depth at this time are, for example, up to the lower surface of the second cladding layer 105.

Process 5: The first cladding layer 103 of the second stacked body and the first multilayer film reflector 102 of the first stacked body are joined by, for example, any one of the joining methods (1) to (4) described above.

Thereafter, processes similar to processes S4 to S11 in FIG. 3 are performed.

With the surface emitting laser 400-1, an effect similar to that of the surface emitting laser 400 of the fourth embodiment can be obtained, and since the first confinement portion C1 is extended to the upstream side of the current passage with respect to the first confinement portion C1 of the surface emitting laser 400, the current confinement effect in the active layer 104 can be obtained at an earlier stage.

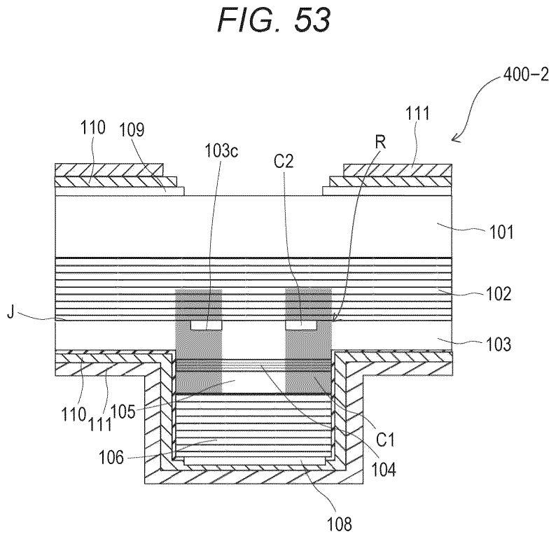

(Modification 2) As illustrated in FIG. 53, a surface emitting laser 400-2 of Modification 2 has a configuration similar to that of the surface emitting laser 400-1 of Modification 1 except that a part of the central portion of the first multilayer film reflector 102 in the thickness direction (a portion on the first cladding layer 103 side) is also surrounded by the first confinement portion C1.

That is, in the surface emitting laser 400-2, the first confinement portion C1 is provided in a region including the first joint surface, which is the joint surface of the first constituent portion with the second constituent portion, of the first constituent portion and a region including the second joint surface, which is the joint surface of the second constituent portion with the first constituent portion, of the second constituent portion of the first constituent portion on one side (for example, the upper side) and the second constituent portion on the other side (for example, the lower side) of the joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

The surface emitting laser 400-2 can be manufactured by a manufacturing method substantially similar to the method for manufacturing the surface emitting laser 400-1 described above. However, in process 1 of the method for manufacturing the surface emitting laser 400-1, after the first multilayer film reflector 102 is stacked on the substrate 101, the ion implantation, the hole diffusion, the impurity diffusion, or the like is performed on the first multilayer film reflector 102 to form the frame-shaped current confinement portion, thereby generating the first confinement portion C1 also in the first multilayer film reflector 102.

With the surface emitting laser 400-2, an effect similar to that of the surface emitting laser 400-1 of Modification 1 can be obtained, and since the first confinement portion C1 is extended to the upstream side of the current path with respect to the first confinement portion C1 of the surface emitting laser 400-1, the current confinement effect in the active layer 104 can be obtained earlier.

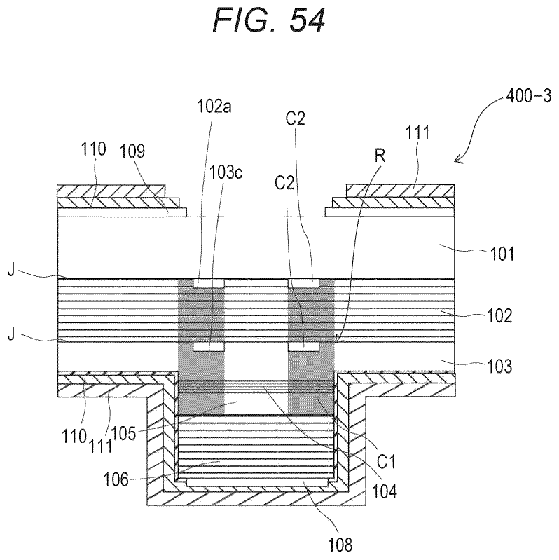

(Modification 3) As illustrated in FIG. 54, in a surface emitting laser 400-3 of Modification 3, the joint portion J exists between the first multilayer film reflector 102 and the first cladding layer 103, and the joint portion J exists in the first structure (for example, between the substrate 101 and the first multilayer film reflector 102). In the surface emitting laser 400-3, the first cladding layer 103 includes a single layer.

In the surface emitting laser 400-3, as an example, the entire region in the thickness direction of the central portion of the first multilayer film reflector 102, the entire region in the thickness direction of the central portion of the first cladding layer 103, the entire region in the thickness direction of the central portion of the active layer 104, and the entire region in the thickness direction of the central portion of the second cladding layer 105 are surrounded by the first confinement portion C1.

In the surface emitting laser 400-3, as an example, the frame-shaped recess 103c (second confinement portion C2) is formed on the joint surface of the first cladding layer 103 with the first multilayer film reflector 102, and the frame-shaped recess 102a (second confinement portion C2) is formed on the joint surface of the first multilayer film reflector 102 with the substrate 101.

That is, in the surface emitting laser 400-3, the one (for example, upper) first confinement portion C1 is provided in a region including the second joint surface, which is the joint surface of the second constituent portion with the first constituent portion, of the second constituent portion of the first constituent portion on one side (for example, the upper side) and the second constituent portion on the other side (for example, the lower side) of the one (for example, upper) joint portion J. Here, the first constituent portion includes the substrate 101. The second constituent portion includes at least the first multilayer film reflector 102 among the first multilayer film reflector 102, the first cladding layer 103, the active layer 104, the second cladding layer 105, and the second multilayer film reflector 106.

In the surface emitting laser 400-3, the other (for example, lower) first confinement portion C1 is provided in a region including the second joint surface, which is the joint surface of the second constituent portion with the first constituent portion, of the second constituent portion of the first constituent portion on one side (for example, the upper side) and the second constituent portion on the other side (for example, the lower side) of the other (for example, lower) joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

In the surface emitting laser 400-3, the one (for example, upper) second confinement portion C2 is provided on a second joint surface, which is a joint surface of the second constituent portion with the first constituent portion, of the first constituent portion on one side (for example, the upper side) and the second constituent portion on the other side (for example, the lower side) of the one (for example, the upper side) joint portion J. Here, the first constituent portion includes the substrate 101. The second constituent portion includes at least the first multilayer film reflector 102 among the first multilayer film reflector 102, the first cladding layer 103, the active layer 104, the second cladding layer 105, and the second multilayer film reflector 106.

In the surface emitting laser 400-3, the other (for example, lower) second confinement portion C2 is provided on a second joint surface which is a joint surface with the first constituent portion of the second constituent portion, of the first constituent portion on one side (for example, the upper side) and the second constituent portion on the other side (for example, the lower side) of the other (for example, lower) joint portion J. Here, the first constituent portion includes at least the first multilayer film reflector 102 of the substrate 101 and the first multilayer film reflector 102. The second constituent portion includes at least the first cladding layer 103 among the first cladding layer 103, the active layer 104, the second cladding layer 105, and the second multilayer film reflector 106.

An example of a method for manufacturing the surface emitting laser 400-3 will be briefly described.

Process 1: The first multilayer film reflector 102 is stacked on a substrate 1 to generate a stacked body 1.

Process 2: The frame-shaped recess 102a is formed by etching the first multilayer film reflector 102 of the stacked body 1, and the semi-insulating material or the insulating material is embedded in the recess 102a as necessary, thereby generating the second confinement portion C2.

Process 3: The ion implantation, the hole diffusion, the impurity diffusion, or the like is performed on the first multilayer film reflector 102 of the stacked body 1 to form the frame-shaped current confinement portion, thereby generating the first confinement portion C1 in the first multilayer film reflector 102.

Process 4: The second multilayer film reflector 106, the second cladding layer 105, the active layer 104, and the first cladding layer 103 are stacked in this order from the substrate 112 side on the substrate 112 to generate the stacked body 2.

Process 5: The frame-shaped recess 103c is formed by etching the first cladding layer 103 of the stacked body 2, and the semi-insulating material or the insulating material is embedded in the recess 103c as necessary, thereby generating the second confinement portion C2 in the first cladding layer 103.

Process 6: The ion implantation, the hole diffusion, the impurity diffusion, or the like is performed on the first cladding layer 103 of the stacked body 2 to form the frame-shaped current confinement portion, thereby generating the first confinement portion C1 in the resonator.

Process 7: The first substrate 101 and the first multilayer film reflector 102 of the stacked body 1 are joined by, for example, any one of the joining methods (1) to (4) described above.

Process 8: The substrate 1 of the stacked body 1 is thinned and removed by wet etching. As a result, the first multilayer film reflector 102 of the stacked body 1 is exposed.

Process 9: The first multilayer film reflector 102 of the stacked body 1 and the first cladding layer 103 of the stacked body 2 are joined by, for example, any one of the joining methods (1) to (4) described above.

Thereafter, processes similar to processes S4 to S11 in FIG. 3 are performed.

With the surface emitting laser 400-3, an effect similar to that of the surface emitting laser 400-2 of Modification 2 can be obtained, and the first confinement portion C1 is extended to the upstream side of the current path with respect to the first confinement portion C1 of the surface emitting laser 400-2, so that the current confinement effect can be obtained from an earlier stage, and since the second confinement portion C2 is also provided in the first multilayer film reflector 102, the light confinement effect to the active layer 104 can be obtained more.

(Modification 4)

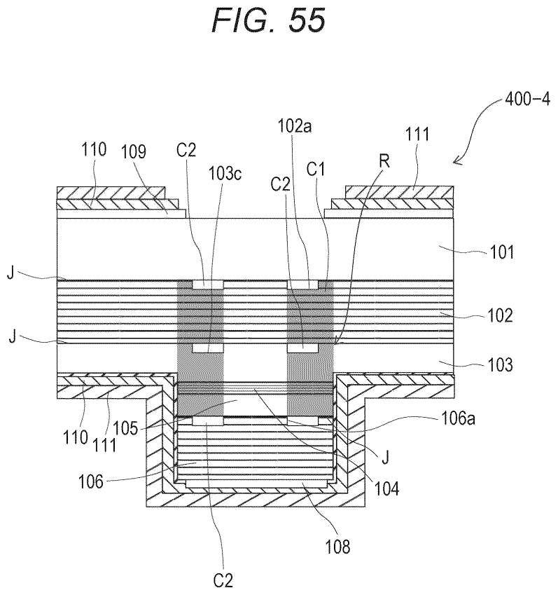

As illustrated in FIG. 55, in the surface emitting laser 400-4 of Modification 3, the joint portion J exists between the first multilayer film reflector 102 and the first cladding layer 103, the joint portion J exists between the substrate 101 and the first multilayer film reflector 102, and the joint portion J exists between the second cladding layer 105 and the second multilayer film reflector 106. In the surface emitting laser 400-4, the first cladding layer 103 includes a single layer.

In the surface emitting laser 400-4, as an example, the entire region in the thickness direction of the central portion of the first multilayer film reflector 102, the entire region in the thickness direction of the central portion of the first cladding layer 103, the entire region in the thickness direction of the central portion of the active layer 104, and the entire region in the thickness direction of the central portion of the second cladding layer 105 are surrounded by the first confinement portion C1.

In a surface emitting laser 400-4, as an example, the frame-shaped recess 103c (second confinement portion C2) is formed on the joint surface of the first cladding layer 103 with the first multilayer film reflector 102, the frame-shaped recess 102a (second confinement portion C2) is formed on the joint surface of the first multilayer film reflector 102 with the substrate 101, and the frame-shaped recess 106a (second confinement portion C2) is formed on the joint surface of the second multilayer film reflector 106 with the second cladding layer 105.

That is, in the surface emitting laser 400-4, the lowermost second confinement portion C2 is provided on the second joint surface, which is a joint surface of the second constituent portion with the first constituent portion, of the first constituent portion on one side (for example, the upper side) and the second constituent portion on the other side (for example, the lower side) of the lowermost joint portion J. Here, the first constituent portion includes at least the second cladding layer 105 among of the substrate 101, the first multilayer film reflector 102, the first cladding layer 103, the active layer 104, and the second cladding layer 105. The second constituent portion includes the second multilayer film reflector 106.

An example of a method for manufacturing the surface emitting laser 400-4 will be briefly described.

Process 1: The first multilayer film reflector 102 is stacked on a substrate 1 to generate the stacked body 1.

Process 2: The frame-shaped recess 102a is formed by etching the first multilayer film reflector 102 of the stacked body 1.

Process 3: The ion implantation, the hole diffusion, the impurity diffusion, or the like is performed on the first multilayer film reflector 102 of the stacked body 1 to form the frame-shaped current confinement portion, thereby generating the first confinement portion C1 in the first multilayer film reflector 102.

Process 4: The second cladding layer 105, the active layer 104, and the first cladding layer 103 are stacked in this order from the substrate 2 side on the substrate 2 to generate the stacked body 2.

Process 5: The frame-shaped recess 103c is formed by etching the first cladding layer 103 of the stacked body 2, and the semi-insulating material or the insulating material is embedded in the recess 103c as necessary, thereby generating the second confinement portion C2 in the first cladding layer 103.

Process 6: The ion implantation, the hole diffusion, the impurity diffusion, or the like is performed on the first cladding layer 103 of the stacked body 2 to form the frame-shaped current confinement portion, thereby generating the first confinement portion C1 in the resonator.

Process 7: The second multilayer film reflector 106 is stacked on the substrate 112 to generate the stacked body 3.

Process 8: A frame-shaped recess 106a is formed by etching the second multilayer film reflector 106 of the stacked body 3, and the semi-insulating material or the insulating material is embedded in the recess 106a as necessary, thereby generating the second confinement portion C2 in the second multilayer film reflector 106.

Process 9: The first substrate 101 and the first multilayer film reflector 102 of the stacked body 1 are joined by, for example, any one of the joining methods (1) to (4) described above.

Process 10: The substrate 1 of the stacked body 1 is thinned and removed by wet etching. As a result, the first multilayer film reflector 102 of the stacked body 1 is exposed.

Process 11: The first multilayer film reflector 102 of the stacked body 1 and the first cladding layer 103 of the stacked body 2 are joined by, for example, any one of the joining methods (1) to (4) described above.

Process 12: The substrate 2 of the stacked body 2 is thinned and removed by wet etching. As a result, the second cladding layer 105 of the stacked body 2 is exposed.

Process 13: The second cladding layer 105 of the stacked body 2 and the second multilayer film reflector 106 of the stacked body 3 are joined by, for example, any one of the joining methods (1) to (4) described above.

Thereafter, processes similar to processes S4 to S11 in FIG. 3 are performed.

With the surface emitting laser 400-4, it is possible to obtain an effect similar to that of the surface emitting laser 400-3 of Modification 2, and it is possible to obtain a more light confinement effect on the active layer 104 since the second confinement portion C2 is also provided in the second multilayer film reflector 106 as compared with the surface emitting laser 400-3.

As can be seen from the above description, in the surface emitting laser of the present technology, the first confinement portion C1 can be formed at a desired position (for example, the joint portion J or a position relatively close to the joint portion J) with excellent width controllability by selecting at least one place where the joint portion J is provided. In the surface emitting laser of the present technology, the second confinement portion C2 can be formed at a desired position (for example, the joint portion J) with excellent width controllability by selecting at least one place where the joint portion J is provided.

8. Configuration Example of Surface Emitting Laser to Which Present Technology Can Be Applied

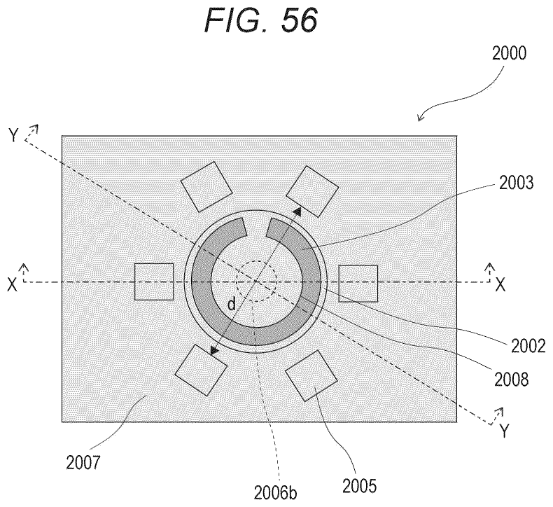

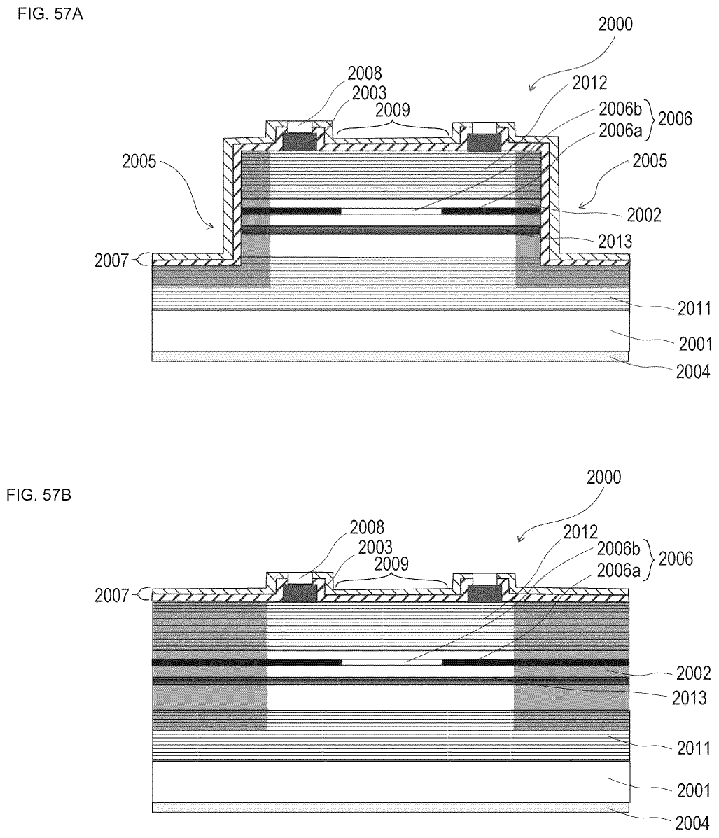

FIG. 56 is a plan view illustrating a surface emitting laser 2000 which is a configuration example of a surface emitting laser to which the present technology can be applied. FIG. 57A is a cross-sectional view taken along line X-X of FIG. 56. FIG. 57B is a cross-sectional view taken along line Y-Y in FIG. 56.

Each component of the surface emitting laser 2000 is stacked on a substrate 2001. The substrate 2001 can include, for example, a semiconductor such as GaAs, InGaAs, InP, or InAsP.

The surface emitting laser 2000 includes a protective region 2002 (the transparent gray region in FIGS. 57A and 57B). As illustrated in FIG. 56, the protective region 2002 has a circular shape in plan view, but may have another shape such as an elliptical shape or a polygonal shape, but is not limited to a specific shape. The protective region 2002 includes a material that provides electrical isolation and is, for example, an ion-implanted region.

Moreover, as illustrated in FIGS. 57A and 57B, the surface emitting laser 2000 includes a first electrode 2003 and a second electrode 2004. As illustrated in FIG. 56, the first electrode 2003 has a ring shape having discontinuous portions (intermittent portions), that is, a split ring shape in plan view, but is not limited to a specific shape. As illustrated in FIG. 57A or 57B, the second electrode 2004 is in contact with the substrate 2001. The first electrode 2003 and the second electrode 2004 include, for example, a conductive material such as Ti, Pt, Au, AuGeNi, or PdGeAu. The first electrode 2003 and the second electrode 2004 may have a single layer structure or a stacked structure.

Moreover, the surface emitting laser 2000 includes a trench 2005 provided around the protective region 2002. FIG. 56 illustrates, as an example, a structure in which the trenches 2005 having a rectangular shape in plan view are provided at 6 portions, but the number of the trenches and the shape in plan view are not limited to specific ones. The trench 2005 is an opening for forming an oxide confinement layer 2006 (including an oxidized region 2006a and a non-oxidized region 2006b). In the manufacturing process of the surface emitting laser 2000, high-temperature water vapor is supplied via the trench 2005 to form the oxidized region 2006a of the oxide confinement layer 2006. For example, the oxidized region 2006a is Al₂O₃formed as a result of the oxidation of the AlAs or AlGaAs layer. An arbitrary dielectric may be embedded in the trench 2005 after the process of forming the oxide confinement layer 2006. In addition, surface coating with a dielectric film may be performed.

Further, the surface emitting laser 2000 includes a dielectric opening 2008 (contact hole) provided in a dielectric layer 2007 on the first electrode 2003. The dielectric layer 2007 may have a stacked structure as illustrated in FIGS. 57A and 57B, or may have a single layer structure. As an example, the dielectric layer 2007 includes silicon oxide, silicon nitride, or the like. As illustrated in FIG. 56, the dielectric opening 2008 is formed in the same shape as the first electrode 2003. However, the shape of the dielectric opening 2008 is not limited to the shape of the first electrode 2003, and may be partially formed on the first electrode 2003. The dielectric opening 2008 is filled with a conductive material (not illustrated), and the conductive material comes into contact with the first electrode 2003.

Moreover, as illustrated in FIGS. 57A and 57B, the surface emitting laser 2000 includes an optical opening 2009 inside the first electrode 2003. The surface emitting laser 2000 emits a light beam through the optical opening 2009. Moreover, in the surface emitting laser 2000, the oxidized region 2006a of the oxide confinement layer 2006 functions as a current/light confinement region that confines current and light. The non-oxidized region 2006b of the oxide confinement layer 2006 is located below the optical opening 2009 and functions as a current/light passing region that passes current and light.

Moreover, the surface emitting laser 2000 includes a first multilayer reflector 2011 and a second multilayer reflector 2012. The multilayer reflector is a semiconductor multilayer reflector as an example, and is also referred to as a distributed Bragg reflector.

Further, the surface emitting laser 2000 includes an active layer 2013. The active layer 2013 is disposed between the first multilayer reflector 2011 and the second multilayer reflector 2012, confines the injected carriers, and defines the emission wavelength of the surface emitting laser 2000.

In the present configuration example, as an example, the case where the surface emitting laser 2000 is a front surface emitting type surface emitting laser has been described as an example, but the surface emitting laser 2000 can also constitute a back surface emitting type surface emitting laser.

As illustrated in FIGS. 56 and 57A, the substantial diameter of the surface emitting laser 2000 of the present configuration example is the diameter d of the virtual circle defined by the trench 2005.

As an example, the surface emitting laser 2000 of the present configuration example is manufactured by the procedure of the following processes 1 to 8.

(Process 1) Epitaxial growth of the first multilayer reflector 2011, the active layer 2013, a selected oxide layer serving as the oxide confinement layer 2006, and the second multilayer reflector 2012 is performed on the front surface of the substrate 2001.

(Process 2) The first electrode 2003 is formed on the second multilayer reflector 2012 using, for example, a lift-off method.

(Process 3) The trench 2005 is formed by, for example, photolithography.

(Process 4) A side surface of the selected oxide layer is exposed, and the oxide confinement layer 2006 is formed by selectively oxidizing the selected oxide layer from the side surface.

(Process 5) The protective region 2002 is formed by the ion implantation or the like.

(Process 6) A film of the dielectric layer 2007 is formed by, for example, vapor deposition, sputtering, or the like.

(Process 7) The dielectric opening 2008 is formed in the dielectric layer 2007 by, for example, photolithography to expose the contact of the first electrode 2003.

(Process 8) After the back surface of the substrate 2001 is polished and thinned, the second electrode 2004 is formed on the back surface of the substrate 2001.

The number of layers, arrangement, thickness, arrangement order, symmetry, and the like of the layers constituting the surface emitting laser 2000 described above are examples, and can be appropriately changed. That is, the surface emitting laser 2000 may include more layers, fewer layers, different layers, layers of different structures, or layers of different arrangements than those illustrated in FIGS. 56, 57A, and 57B.

The present technology can be applied to the surface emitting laser 2000 described above and modifications thereof.

9. Modification Example of Present Technology The present technology is not limited to each of the embodiments and modifications described above, and various modifications can be made.

In the surface emitting laser of the present technology, the joint portion J is only required to exist in at least one of inside the first structure, inside the second structure, inside the resonator, between the resonator and the first structure, or between the resonator and the second structure. Moreover, in the surface emitting laser of the present technology, it is preferable that the first confinement portion C1 that confines a current is provided in at least one of first or second constituent portion joined at the joint portion J, and the second confinement portion C2 that confines at least light of a current or light is provided in at least one of the first or second constituent portion.

The first and second confinement portions C1 and C2 may be provided in one of the first and second constituent portions.

The first confinement portion C1 may be provided in one of the first and second constituent portions, and the second confinement portion C2 may be provided in the other.

The second confinement portion may be provided on a first joint surface that is a joint surface of the first constituent portion with the second constituent portion and/or a second joint surface that is a joint surface of the second constituent portion with the first constituent portion.

The first confinement portion may be provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

The first confinement portion may be provided in a region of the first constituent portion including a first joint surface that is a joint surface of the first constituent portion with the second constituent portion and/or a region of the second constituent portion including a second joint surface that is a joint surface of the second constituent portion with the first constituent portion.

For example, in each of the embodiments and modifications described above, the impurity diffusion (for example, the ion implantation, the hole diffusion, the impurity diffusion, or the like) is performed before joining between the components to form the first confinement portion C1 at the time of manufacturing the surface emitting laser, but the ion implantation, the hole diffusion, the impurity diffusion, or the like may be performed after joining between the components to form the first confinement portion C1.

For example, the surface emitting laser of the present technology may have four or more joint portions J.

For example, in the surface emitting laser of the present technology, the joint portion J may exist in the substrate 101. In this case, the first confinement portion C1 and/or the second confinement portion C2 may be provided in the substrate 101.

For example, in the surface emitting laser of the present technology, the joint portion J may exist in the first multilayer film reflector 102 and/or the second multilayer film reflector 106. In this case, the first confinement portion C1 and/or the second confinement portion C2 may be provided in the first multilayer film reflector 102 and/or the second multilayer film reflector 106.

For example, in each of the embodiments and modifications described above, the first confinement portion C1 is continuously and integrally provided, but a plurality of the first confinement portions C1 may be discontinuously and separately provided.

For example, in each of the embodiments and modifications described above, the substrate 101 of the surface emitting laser may be Si, GaN, InP, or the like. The surface emitting laser of the present technology can use a material having any oscillation wavelength included in the wavelength band of 200 to 2000 nm.

For example, in each of the embodiments and modifications described above, each of the first and second multilayer film reflectors 102 and 106 may be formed by a dielectric or a metal.

For example, in each of the embodiments and modifications described above, the pad wiring 110 may be formed by a plating method (the pad wiring 110 may be a plated wiring).

For example, in each of the embodiments and modifications described above, a wiring (wiring other than plated wiring) may be formed on the pad wiring 110 by, for example, a lift-off method instead of the plated wiring 111.

For example, in each of the embodiments and modifications described above, one of the pad wiring 110 and the plated wiring 111 may not be provided.

For example, in each of the embodiments and modifications described above, the surface emitting laser may not have a mesa.

For example, in each of the embodiments and modifications described above, the surface emitting laser may have a structure in which carriers are injected into the active layer 104 by light. In this case, each electrode and each wiring are unnecessary.

For example, in each of the embodiments and modifications described above, the surface emitting laser may be a gain guide type in which the second confinement portion C2 is not provided and only the first confinement portion C1 is provided.

For example, in each of the embodiments and modifications described above, the surface emitting laser may be a gain guide type in which the second confinement portion C2 as the current confinement portion is formed by embedding, in the joint portion J or the frame-shaped recess provided near the joint portion J, a material having a refractive index higher than that of the central portion surrounded by the recess.

For example, in each of the embodiments and modifications described above, a contact layer in contact with an electrode may be provided on the top of the mesa.

For example, in each of the embodiments and modifications described above, the first structure including the substrate 101 and the first multilayer film reflector 102 may have a buffer layer between the substrate 101 and the first multilayer film reflector 102. In this case, the joint portion J may exist inside at least one of the substrate 101, the first multilayer film reflector 102, or the buffer layer, or the joint portion J may exist between the substrate 101 and the buffer layer and/or between the buffer layer and the first multilayer film reflector 102. In this case, the first confinement portion C1 may be provided in the joint portion J or other than the joint portion J, or the second confinement portion C2 may be provided in the joint portion J.

For example, a surface emitting laser array can include a plurality of the surface emitting lasers of any one of the embodiments and modifications described above.

Some of the configurations of the surface emitting laser of each of the above embodiments and modifications may be combined within a range in which they do not contradict each other.

In each embodiment and each modification described above, the material, conductivity type, thickness, numerical value of width, and the like of each layer constituting the surface emitting laser can be appropriately changed within a range functioning as the surface emitting laser.

10. Application Example to Electronic Device The technology according to the present disclosure (the present technology) can be applied to various products (electronic devices). For example, the technology according to the present disclosure may also be achieved as a device mounted on any type of mobile body such as an automobile, an electric vehicle, a hybrid electric vehicle, a motorcycle, a bicycle, a personal mobility, an airplane, a drone, a boat, a robot, and the like.

The surface emitting laser according to the present technology can also be applied as, for example, a light source of a device that forms or displays an image by laser light (for example, a laser printer, a laser copier, a projector, a head-mounted display, a head-up display, or the like).

### 11. <Example in Which Surface Emitting Laser Is Applied to Distance Measuring Device>

Hereinafter, application examples of the surface emitting laser according to each of the embodiments and modifications described above will be described.

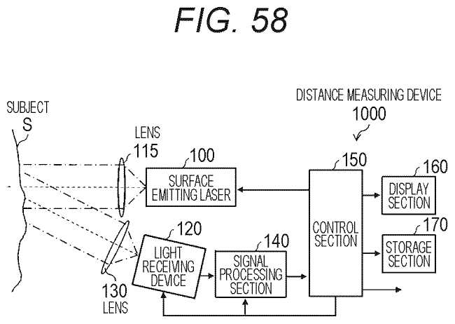

FIG. 58 illustrates an example of a schematic configuration of a distance measuring device 1000 including a surface emitting laser 100 as an example of an electronic device according to the present technology. The distance measuring device 1000 measures a distance to a subject S by a time of flight (TOF) method. The distance measuring device 1000 includes the surface emitting laser 100 as a light source. The distance measuring device 1000 includes, for example, a surface emitting laser 100, a light receiving device 120, lenses 115 and 130, a signal processing section 140, a control section 150, a display section 160, and a storage section 170.

The light receiving device 120 detects light reflected by the subject S. The lens 115 is a lens for collimating the light emitted from the surface emitting laser 100, and is a collimating lens. The lens 130 is a lens for condensing light reflected by the subject S and guiding the light to the light receiving device 120, and is a condenser lens.

The signal processing section 140 is a circuit for generating a signal corresponding to a difference between a signal inputted from the light receiving device 120 and a reference signal inputted from the control section 150. The control section 150 includes, for example, a time-to-digital converter (TDC).

The reference signal may be a signal input from the control section 150, or may be an output signal of a detection section that directly detects the output of the surface emitting laser 100. The control section 150 is, for example, a processor that controls the surface emitting laser 100, the light receiving device 120, the signal processing section 140, the display section 160, and the storage section 170. The control section 150 is a circuit that measures a distance to the subject S on the basis of a signal generated by the signal processing section 140. The control section 150 generates a video signal for displaying information about a distance to the subject S, and outputs the video signal to the display section 160. The display section 160 displays information about the distance to the subject S, on the basis of the video signal inputted from the control section 150. The control section 150 stores information about the distance to the subject S in the storage section 170.

In the present application example, instead of the surface emitting laser 100, any one of the surface emitting lasers 100-1 to 100-15, 200, 300, 400, and 400-1 to 400-4 described above can be applied to the distance measuring device 1000.

### 12. <Example in Which Distance Measuring Device Is Mounted on Mobile Body>

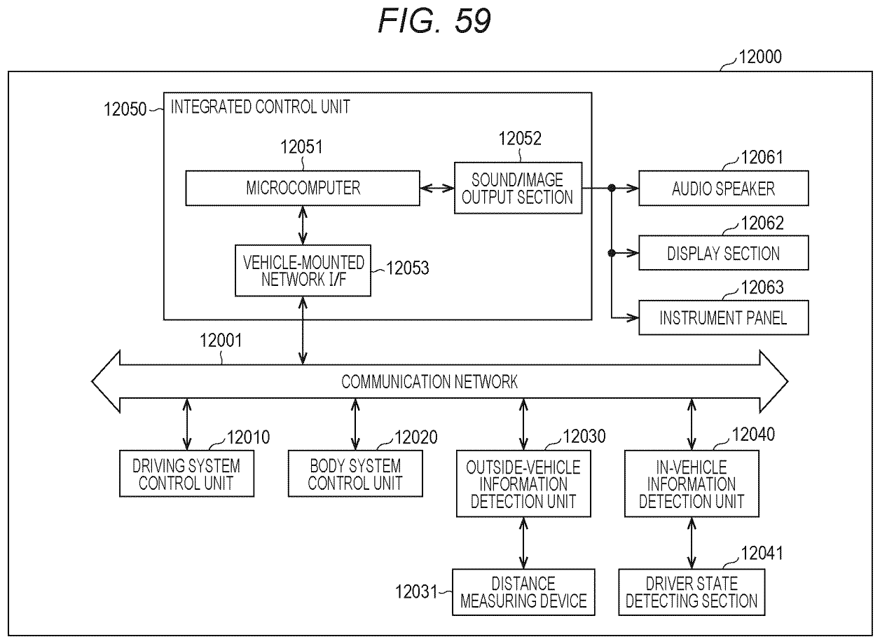

FIG. 59 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example illustrated in FIG. 59, the vehicle control system 12000 is provided with a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back lamp, a brake lamp, a turn indicator, or a fog lamp. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the above-described distance measuring device 1000. The outside-vehicle information detecting unit 12030 causes the distance measuring device 12031 to measure a distance to an object (the subject S) outside the vehicle, and acquires distance data obtained by the measurement. The outside-vehicle information detecting unit 12030 may perform object detection processing of a person, a vehicle, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041 includes, for example, a camera that captures an image of the driver, and the in-vehicle information detecting unit 12040 may calculate the degree of fatigue or the degree of concentration of the driver or may determine whether or not the driver is dozing off on the basis of the detection information input from the driver state detecting section 12041.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of information about the outside of the vehicle, the information being acquired by the outside-vehicle information detecting unit 12030. For example, the microcomputer 12051 can perform cooperative control intended to prevent a glare by controlling the headlamp, such as changing from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or auditorily notifying an occupant of the vehicle or the outside of the vehicle of information. In the example in FIG. 59, an audio speaker 12061, a display section 12062, and an instrument panel 12063 are exemplified as the output device. The display section 12062 may, for example, include at least one of an on-board display or a head-up display.

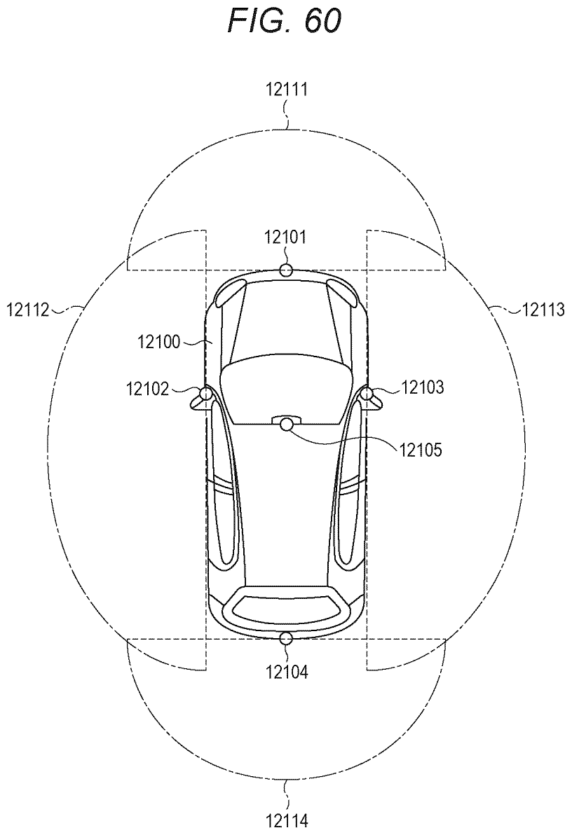

FIG. 60 is a view illustrating an example of an installation position of the distance measuring device 12031.

In FIG. 60, a vehicle 12100 includes distance measuring devices 12101, 12102, 12103, 12104, and 12105 as the distance measuring device 12031.

The distance measuring devices 12101, 12102, 12103, 12104, and 12105 are provided at positions such as, for example, a front nose, side mirrors, a rear bumper, a back door, and an upper part of a windshield in a vehicle cabin, of the vehicle 12100. The distance measuring device 12101 provided on the front nose and the distance measuring device 12105 provided on the upper part of the windshield in the cabin mainly acquire data of the front of the vehicle 12100. The distance measuring devices 12102 and 12103 provided in the side mirrors mainly acquire data of sides of the vehicle 12100. The distance measuring device 12104 provided in the rear bumper or the back door mainly acquires data of the rear of the vehicle 12100. The data of the front side acquired by the distance measuring devices 12101 and 12105 is mainly used for detecting a preceding vehicle, a pedestrian, an obstacle, a traffic light, a traffic sign, or the like.

Note that FIG. 60 illustrates an example of detection ranges of the distance measuring devices 12101 to 12104. A detection range 12111 indicates a detection range of the distance measuring device 12101 provided on the front nose, detection ranges 12112 and 12113 indicate detection ranges of the distance measuring devices 12102 and 12103 provided in the side mirrors, respectively, and a detection range 12114 indicates a detection range of the distance measuring device 12104 provided in the rear bumper or the back door.

For example, the microcomputer 12051 can determine a distance to each three-dimensional object within the detection ranges 12111 to 12114 and a temporal change in the distance (a relative speed with respect to the vehicle 12100) on the basis of the distance data obtained from the distance measuring devices 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Moreover, the microcomputer 12051 can set an inter-vehicle distance to be secured from a preceding vehicle in advance, and perform automatic brake control (including follow-up stop control), automatic acceleration control (including follow-up start control), and the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance data obtained from the distance measuring devices 12101 to 12104, extract the classified three-dimensional object data, and use the extracted three-dimensional object data for automatic avoidance of an obstacle. For example, the microcomputer 12051 distinguishes obstacles around the vehicle 12100 into obstacles that are visible to the driver of the vehicle 12100 and obstacles that are difficult to see. Then, the microcomputer 12051 determines a collision risk indicating a risk of collision with each obstacle, and when the collision risk is equal to or higher than a set value and there is a possibility of collision, the microcomputer 12051 can perform driving assistance for collision avoidance by outputting an alarm to the driver via the audio speaker 12061 or the display section 12062 or performing forced deceleration or avoidance steering via the driving system control unit 12010.

An example of the mobile body control system to which the technology according to the present disclosure can be applied has been described above. The technology according to the present disclosure can be applied to the distance measuring device 12031 among the configurations described above.

The specific numerical values, shapes, materials (including compositions), and the like described in the present description are merely examples, and are not limited thereto.

Furthermore, the present technology can also have the following configurations.

(1) A surface emitting laser, including:
a first structure including a first multilayer film reflector;
a second structure including a second multilayer film reflector; and
a resonator disposed between the first and second structures and including an active layer, in which
a joint portion exists in at least one of inside the first structure, inside the second structure, inside the resonator, between the resonator and the first structure, or between the resonator and the second structure, and
a first confinement portion that confines a current is provided in at least one of a first constituent portion on one side or a second constituent portion on another side of the joint portion, and a second confinement portion that confines at least light of a current or light is provided in at least one of the first or second constituent portion.

(2) The surface emitting laser according to (1), in which the first and second confinement portions are provided in one of the first and second constituent portions.

(3) The surface emitting laser according to (1), in which the first confinement portion is provided in one of the first and second constituent portions, and the second confinement portion is provided in the other.

(4) The surface emitting laser according to any one of (1) to (3), in which the second confinement portion is provided on a first joint surface that is a joint surface of the first constituent portion with the second constituent portion and/or a second joint surface that is a joint surface of the second constituent portion with the first constituent portion.

(5) The surface emitting laser according to any one of (1) to (4), in which the first confinement portion is provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

(6) The surface emitting laser according to any one of (1) to (4), in which the first confinement portion is provided in a region of the first constituent portion including a first joint surface that is a joint surface of the first constituent portion with the second constituent portion and/or a region of the second constituent portion including a second joint surface that is a joint surface of the second constituent portion with the first constituent portion.

(7) The surface emitting laser according to any one of (1) to (3), in which the second confinement portion is provided on a first joint surface that is a joint surface of the first constituent portion with the second constituent portion and/or a second joint surface that is a joint surface of the second constituent portion with the first constituent portion, and the first confinement portion is provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

(8) The surface emitting laser according to any one of (1) to (3), in which the second confinement portion is provided on a first joint surface that is a joint surface of the first constituent portion with the second constituent portion and/or a second joint surface that is a joint surface of the second constituent portion with the first constituent portion, and the first confinement portion is provided in a region of the first constituent portion including a first joint surface that is a joint surface of the first constituent portion with the second constituent portion and/or a region of the second constituent portion including a second joint surface that is a joint surface of the second constituent portion with the first constituent portion.

(9) The surface emitting laser according to any one of (1) to (8), in which the resonator further includes first and second cladding layers disposed at positions sandwiching the active layer, and the joint portion exists inside at least one of the first or second cladding layer.

(10) The surface emitting laser according to (4), in which the second confinement portion is a layer provided on at least one of the first or second joint surface and existing in a circular recessed portion.

(11) The surface emitting laser according to (10), in which the layer is a low refractive index layer having a lower refractive index than a refractive index of a portion of the first constituent portion and/or the second constituent portion inside the recess.

(12) The surface emitting laser according to (11), in which the low refractive index layer has a semi-insulating property or an insulating property.

(13) The surface emitting laser according to any one of (10) to (12), in which the layer has a semi-insulating property or an insulating property.

(14) The surface emitting laser according to any one of (10) to (13), in which a cross section of the recess has a shape that becomes shallower as approaching the at least part of the central portion.

(15) The surface emitting laser according to any one of (1) to (14), in which the first confinement portion has a higher electrical resistance than a portion surrounded by the first confinement portion.

(16) The surface emitting laser according to (15), in which the first confinement portion is a layer into which ions are implanted.

(17) The surface emitting laser according to any one of (1) to (14), in which the first confinement portion and a portion surrounded by the first confinement portion are formed by a compound semiconductor, and the first confinement portion has a larger band gap than a portion surrounded by the first confinement portion.

(18) The surface emitting laser according to any one of (1) to (14), in which the first confinement portion is a layer in which impurities are diffused.

(19) The surface emitting laser according to any one of (1) to (14), in which the first confinement portion is a layer into which ions are implanted and impurities are diffused.

(20) The surface emitting laser according to (17), in which the first confinement portion is a layer into which ions are implanted and/or impurities are diffused.

(21) A surface emitting laser array including a plurality of the surface emitting lasers according to any one of (1) to (20).

(22) An electronic device including the surface emitting laser according to any one of (1) to (20).

(23) A method for manufacturing a surface emitting laser, the method including:
a process of stacking a first structure including a first multilayer film reflector and a first portion of a resonator in this order on a first substrate to generate a first stacked body;
a process of generating a second stacked body; and
a process of joining the first and second stacked bodies, in which
in the process of generating the second stacked body,
a second structure including a second multilayer film reflector and a second portion of the resonator are stacked in this order on a second substrate,
at least one of ion implantation, hole diffusion, or impurity diffusion is performed on the second portion to form a frame-shaped current confinement portion,
a third portion of the resonator is stacked on the second portion of the resonator,
a frame-shaped recess is formed in the third portion of the resonator, and
in the joining process, the third portion of the resonator in the second stacked body and the first portion of the resonator in the first stacked body are joined.

(24) The method for manufacturing a surface emitting laser according to (23), in which in the process of generating the first stacked body, after the first structure is stacked on the first substrate and before the first portion of the resonator is stacked on the first structure, at least one of ion implantation, hole diffusion, or impurity diffusion is performed on the first structure to form a frame-shaped current confinement portion.

(25) The method for manufacturing a surface emitting laser according to (23) or (24), in which in the process of generating the first stacked body, the first structure is stacked on the first substrate, and after the first portion of the resonator is stacked on the first structure, at least one of ion implantation, hole diffusion, or impurity diffusion is performed on the first portion to form a frame-shaped current confinement portion.

(26) The method for manufacturing a surface emitting laser according to any one of (23) to (25), in which in the process of generating the first stacked body, a frame-shaped recess is formed in the first structure after the first structure is stacked on the first substrate and before the first portion of the resonator is stacked on the first structure.

(27) The method for manufacturing a surface emitting laser according to any one of (23) to (26), in which in the process of generating the first stacked body, the first structure is stacked on the first substrate, and after the first portion of the resonator is stacked on the first structure, at least one of ion implantation, hole diffusion, or impurity diffusion is performed on the first portion to form a frame-shaped current confinement portion.

(28) The method for manufacturing a surface emitting laser according to any one of (23) to (26), in which in the process of generating the second stacked body, after the second structure is stacked on the second substrate and before the second portion of the resonator is stacked on the second structure, at least one of ion implantation, hole diffusion, or impurity diffusion is performed on the second structure to form a frame-shaped current confinement portion.

(29) The method for manufacturing a surface emitting laser according to any one of (23) to (28), in which in the process of generating the second stacked body, the second structure is stacked on the second substrate, and after the second portion of the resonator is stacked on the second structure, at least one of ion implantation, hole diffusion, or impurity diffusion is performed on the second portion to form a frame-shaped current confinement portion.

(30) The method for manufacturing a surface emitting laser according to any one of (23) to (29), in which in the process of generating the second stacked body, after the second structure is stacked on the second substrate and before the second portion of the resonator is stacked on the second structure, a frame-shaped recess is formed in the second structure.

(31) The method for manufacturing a surface emitting laser according to any one of (23) to (30), in which in the process of generating the second stacked body, the second structure is stacked on the second substrate, and after the second portion of the resonator is stacked on the second structure, a frame-shaped recess is formed in the second portion.

(32) The method for manufacturing a surface emitting laser according to any one of (23) to (31), further including, after the joining process, a process of performing at least one of ion implantation, hole diffusion, or impurity diffusion on the first stacked body and/or the second stacked body to form a frame-shaped current confinement portion.

(33) A method for manufacturing a surface emitting laser, the method including
a process of stacking a first structure including a first multilayer film reflector and a first portion of a resonator in this order on a first substrate to generate a first stacked body;
a process of generating a second stacked body; and
a process of joining the first and second stacked bodies, in which
in the process of generating the second stacked body, a second structure including a second multilayer film reflector and a second portion of the resonator are stacked in this order on a second substrate, a frame-shaped recess is formed in the second portion, and
in the joining process, the second portion of the resonator in the second stacked body and the first portion of the resonator in the first stacked body are joined.

(34) The method for manufacturing a surface emitting laser according to (33), in which in the process of generating the second stacked body, after the recess is formed and before the joining process, at least one of ion implantation, hole diffusion, or impurity diffusion is performed on the second portion to form a frame-shaped current confinement portion.

(35) The method for manufacturing a surface emitting laser according to (33) or (34), in which in the process of generating the second stacked body, after the second structure including the second multilayer film reflector and the second portion of the resonator are stacked in this order on the second substrate and before the recess is formed, at least one of ion implantation, hole diffusion, or impurity diffusion is performed on the second portion to form a frame-shaped current confinement portion.

(36) The method for manufacturing a surface emitting laser according to any one of (33) to (35), in which in the process of generating the first stacked body, after the first structure is stacked on the first substrate and before the first portion of the resonator is stacked on the first structure, at least one of ion implantation, hole diffusion, or impurity diffusion is performed on the first structure to form a frame-shaped current confinement portion.

(37) The method for manufacturing a surface emitting laser according to any one of (33) to (36), in which in the process of generating the first stacked body, after the first structure is stacked on the first substrate and before the first portion of the resonator is stacked on the first structure, a frame-shaped recess is formed in the first structure.

(38) The method for manufacturing a surface emitting laser according to any one of (33) to (37), in which in the process of generating the first stacked body, the first structure is stacked on the first substrate, and after the first portion of the resonator is stacked on the first structure, at least one of ion implantation, hole diffusion, or impurity diffusion is performed on the first portion to form a frame-shaped current confinement portion.

(39) The method for manufacturing a surface emitting laser according to any one of (33) to (38), in which in the process of generating the first stacked body, the first structure is stacked on the first substrate, and after the first portion of the resonator is stacked on the first structure, a frame-shaped recess is formed in the first portion.

(40) The method for manufacturing a surface emitting laser according to any one of (33) to (39), in which in the process of generating the second stacked body, after the second structure is stacked on the second substrate and before the second portion of the resonator is stacked on the second structure, at least one of ion implantation, hole diffusion, or impurity diffusion is performed on the second structure to form a frame-shaped current confinement portion.

(41) The method for manufacturing a surface emitting laser according to any one of (33) to (40), in which in the process of generating the second stacked body, after the second structure is stacked on the second substrate and before the second portion of the resonator is stacked on the second structure, a frame-shaped recess is formed in the second structure.

(42) The method for manufacturing a surface emitting laser according to any one of (33) to (41), in which in the process of generating the second stacked body, the second structure is stacked on the second substrate, and after the second portion of the resonator is stacked on the second structure, at least one of ion implantation, hole diffusion, or impurity diffusion is performed on the second portion to form a frame-shaped current confinement portion.

(43) The method for manufacturing a surface emitting laser according to any one of (33) to (42), in which in the process of generating the second stacked body, the second structure is stacked on the second substrate, and after the second portion of the resonator is stacked on the second structure, a frame-shaped recess is formed in the second portion.

(44) The method for manufacturing a surface emitting laser according to any one of (33) to (43), further including, after the joining process, a process of performing at least one of ion implantation, hole diffusion, or impurity diffusion on the first stacked body and/or the second stacked body to form a frame-shaped current confinement portion.

(45) A method for manufacturing a surface emitting laser, the method including
a process of stacking a first structure including a first multilayer film reflector and a first portion of a resonator on a first substrate to generate a first stacked body;
a process of generating a second stacked body; and
a process of joining the first and second stacked bodies, in which
in the process of generating the second stacked body,
a second structure including a second multilayer film reflector and a second portion of the resonator are stacked on a second substrate,
at least one of ion implantation, hole diffusion, or impurity diffusion is performed on the second portion of the resonator to form a frame-shaped current confinement portion, and
in the joining process, the second portion of the resonator in the second stacked body and the first portion of the resonator in the first stacked body are joined.

(46) The method for manufacturing a surface emitting laser according to (45), in which in the process of generating the second stacked body, after forming the frame-shaped current confinement portion and before the joining process, a frame-shaped recess portion is formed in the second portion.

(47) The method for manufacturing a surface emitting laser according to (45) or (46), in which in the process of generating the second stacked body, after the second structure including the second multilayer film reflector and the second portion of the resonator are stacked in this order on the second substrate and before the frame-shaped current confinement portion is formed, a frame-shaped recess portion is formed in the second portion.

(48) The method for manufacturing a surface emitting laser according to any one of (45) to (47), in which in the process of generating the first stacked body, after the first structure is stacked on the first substrate and before the first portion of the resonator is stacked on the first structure, at least one of ion implantation, hole diffusion, or impurity diffusion is performed on the first structure to form a frame-shaped current confinement portion.

(49) The method for manufacturing a surface emitting laser according to any one of (45) to (48), in which in the process of generating the first stacked body, after the first structure is stacked on the first substrate and before the first portion of the resonator is stacked on the first structure, a frame-shaped recess is formed in the first structure.

(50) The method for manufacturing a surface emitting laser according to any one of (45) to (49), in which in the process of generating the first stacked body, the first structure is stacked on the first substrate, and after the first portion of the resonator is stacked on the first structure, at least one of ion implantation, hole diffusion, or impurity diffusion is performed on the first portion to form a frame-shaped current confinement portion.

(51) The method for manufacturing a surface emitting laser according to any one of (45) to (50), in which in the process of generating the first stacked body, the first structure is stacked on the first substrate, and after the first portion of the resonator is stacked on the first structure, a frame-shaped recess is formed in the first portion.

(52) The method for manufacturing a surface emitting laser according to any one of (45) to (51), in which in the process of generating the second stacked body, after the second structure is stacked on the second substrate and before the second portion of the resonator is stacked on the second structure, at least one of ion implantation, hole diffusion, or impurity diffusion is performed on the second structure to form a frame-shaped current confinement portion. (53) The method for manufacturing a surface emitting laser according to any one of (45) to (52), in which in the process of generating the second stacked body, after the second structure is stacked on the second substrate and before the second portion of the resonator is stacked on the second structure, a frame-shaped recess is formed in the second structure.

(54) The method for manufacturing a surface emitting laser according to any one of (45) to (53), in which in the process of generating the second stacked body, the second structure is stacked on the second substrate, and after the second portion of the resonator is stacked on the second structure, at least one of ion implantation, hole diffusion, or impurity diffusion is performed on the second portion to form a frame-shaped current confinement portion.

(55) The method for manufacturing a surface emitting laser according to any one of (45) to (54), in which in the process of generating the second stacked body, the second structure is stacked on the second substrate, and after the second portion of the resonator is stacked on the second structure, a frame-shaped recess is formed in the second portion.

(56) The method for manufacturing a surface emitting laser according to any one of (45) to (55), further including, after the joining process, a process of performing at least one of ion implantation, hole diffusion, or impurity diffusion on the first stacked body and/or the second stacked body to form a frame-shaped current confinement portion.

(57) The method for manufacturing a surface emitting laser according to any one of (45) to (56), further including, after the joining process, a process of performing at least one of ion implantation, hole diffusion, or impurity diffusion on the first stacked body and/or the second stacked body to form a frame-shaped current confinement portion.

### REFERENCE SIGNS LIST

100, 100-1 to 100-15, 200, 300, 400, 400-1 to 400-4 Surface emitting laser
101 Substrate
102 First multilayer film reflector
103 First cladding layer
103a First constituent layer (at least part of first constituent portion)
103b Second constituent layer (at least part of second constituent portion)
103b1, 103a1, 103c, 102a, 105a, 106a Recess
104 Active layer
105 Second cladding layer
106 Second multilayer film reflector
C1 First confinement portion
C2 Second confinement portion
R Resonator
S1 First structure
S2 Second structure
J Joint portion
JS1 First joint surface
JS2 Second joint surface
1000 Distance measuring device (electronic device)

1. A surface emitting laser, comprising:
a first structure including a first multilayer film reflector;
a second structure including a second multilayer film reflector; and
a resonator disposed between the first and second structures and including an active layer, wherein
a joint portion exists in at least one of inside the first structure, inside the second structure, inside the resonator, between the resonator and the first structure, or between the resonator and the second structure, and
a first confinement portion that confines a current is provided in at least one of a first constituent portion on one side or a second constituent portion on another side of the joint portion, and a second confinement portion that confines at least light of a current or light is provided in at least one of the first or second constituent portion.

2. The surface emitting laser according to claim 1,
wherein the first and second confinement portions are provided in one of the first and second constituent portions.

3. The surface emitting laser according to claim 1,
wherein the first confinement portion is provided in one of the first and second constituent portions, and the second confinement portion is provided in the other.

4. The surface emitting laser according to claim 1, wherein the second confinement portion is provided on a first joint surface that is a joint surface of the first constituent portion with the second constituent portion and/or a second joint surface that is a joint surface of the second constituent portion with the first constituent portion.

5. The surface emitting laser according to claim 1, wherein the first confinement portion is provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

6. The surface emitting laser according to claim 1, wherein the first confinement portion is provided in a region of the first constituent portion including a first joint surface that is a joint surface of the first constituent portion with the second constituent portion and/or a region of the second constituent portion including a second joint surface that is a joint surface of the second constituent portion with the first constituent portion.

7. The surface emitting laser according to claim 1, wherein
the second confinement portion is provided on a first joint surface that is a joint surface of the first constituent portion with the second constituent portion and/or a second joint surface that is a joint surface of the second constituent portion with the first constituent portion, and
the first confinement portion is provided in a region of the first constituent portion not including a first joint surface that is a joint surface of the first constituent portion with the second constituent portion and/or a region of the second constituent portion not including a second joint surface that is a joint surface of the second constituent portion with the first constituent portion.

8. The surface emitting laser according to claim 1, wherein
the second confinement portion is provided on a first joint surface that is a joint surface of the first constituent portion with the second constituent portion and/or a second joint surface that is a joint surface of the second constituent portion with the first constituent portion, and
the first confinement portion is provided in a region of the first constituent portion including a first joint surface that is a joint surface of the first constituent portion with the second constituent portion and/or a region of the second constituent portion including a second joint surface that is a joint surface of the second constituent portion with the first constituent portion.

9. The surface emitting laser according to claim 1, wherein
the resonator further includes first and second cladding layers disposed at positions sandwiching the active layer, and the joint portion exists inside at least one of the first or second cladding layer.

10. The surface emitting laser according to claim 4, wherein the second confinement portion is a layer provided on at least one of the first or second joint surface and existing in a circular recessed portion.

11. The surface emitting laser according to claim 10, wherein the layer is a low refractive index layer having a lower refractive index than a refractive index of a portion of the first constituent portion and/or the second constituent portion inside the recess.

12. The surface emitting laser according to claim 11, wherein the low refractive index layer has a semi-insulating property or an insulating property.

13. The surface emitting laser according to claim 10, wherein the layer has a semi-insulating property or an insulating property.

14. The surface emitting laser according to claim 10, wherein a cross section of the recess has a shape that becomes shallower as approaching the at least part of the central portion.

15. The surface emitting laser according to claim 1, wherein the first confinement portion has a higher electrical resistance than a portion surrounded by the first confinement portion.

16. The surface emitting laser according to claim 15, wherein the first confinement portion is a layer into which ions are implanted.

17. The surface emitting laser according to claim 1, wherein
the first confinement portion and a portion surrounded by the first confinement portion are formed by a compound semiconductor, and
the first confinement portion has a larger band gap than a portion surrounded by the first confinement portion.

18. The surface emitting laser according to claim 1, wherein the first confinement portion is a layer in which impurities are diffused.

19. The surface emitting laser according to claim 1, wherein the first confinement portion is a layer into which ions are implanted and impurities are diffused.

20. The surface emitting laser according to claim 17, wherein the first confinement portion is a layer into which ions are implanted and/or impurities are diffused.
